(19) United States
(12) Patent Application Publication
(10) Pub. No.: US 2025/0013089 A1
(43) Pub. Date: Jan. 9, 2025

(54) IMAGE DISPLAY DEVICE LAMINATE, IMAGE DISPLAY DEVICE, AND MODULE

(71) Applicant: DAI NIPPON PRINTING CO., LTD., Tokyo-to (JP)

(72) Inventors: Masashi SAKAKI, Tokyo-to (JP); Kazuki KINOSHITA, Tokyo-to (JP); Keita IIMURA, Tokyo-to (JP); Seiji TAKE, Tokyo-to (JP); Shuji KAWAGUCHI, Tokyo-to (JP)

(73) Assignee: DAI NIPPON PRINTING CO., LTD., Tokyo-to (JP)

(21) Appl. No.: 18/697,777

(22) PCT Filed: Oct. 4, 2022
(86) PCT No.: PCT/JP2022/037192

§ 371 Date: Apr. 2, 2024

(30) Foreign Application Priority Data
Oct. 4, 2021 (JP) 2021-163754
Oct. 4, 2021 (JP) 2021-163763
Oct. 4, 2021 (JP) 2021-163765
Oct. 7, 2021 (JP) 2021-165702

(51) Int. Cl. G02F 1/1333; H01Q 1/22; H05K 1/18; H10K 59/131

(52) U.S. Cl. CPC G02F 1/1333; H01Q 1/22; H05K 1/181; H10K 59/131; H05K 2201/10128

(57) ABSTRACT

An image display device laminate includes a wiring board that has a substrate and a mesh wiring layer disposed on a first face of the substrate, a first adhesive layer situated on the first face side of the substrate, a second adhesive layer situated on the second face side of the substrate, and an intermediate layer situated in at least one of a position between the wiring board and the first adhesive layer and a position between the wiring board and the second adhesive layer. The substrate has transparency. A partial region of the substrate is disposed in a partial region between the first adhesive layer and the second adhesive layer.

### TECHNICAL FIELD

An embodiment according to the present disclosure relates to an image display device laminate, an image display device, and a module.

### BACKGROUND ART

Increased performance, reduction in size, reduction in thickness, and reduction in weight are currently advancing for mobile terminal equipment, such as smartphones, tablets, and so forth. Such mobile terminal equipment uses a plurality of communication bands. Accordingly, a plurality of antennas are required in accordance with the communication bands. For example, mobile terminal equipment is equipped with a plurality of antennas, such as an antenna for telephone, an antenna for WiFi (Wireless Fidelity), an antenna for 3G (Generation), an antenna for 4G (Generation), an antenna for LTE (Long Term Evolution), an antenna for Bluetooth (registered trademark), an antenna for NFC (Near Field Communication), and so forth. However, due to reduction in size of mobile terminal equipment, space for installing antennas is limited, and the degree in freedom for antenna design is becoming narrower. Also, antennas are built into limited space, and accordingly radio wave sensitivity is not necessarily satisfactory.

Accordingly, film antennas that can be installed in display regions of mobile terminal equipment have been developed. Such film antennas are transparent antennas in which an antenna pattern is formed on a transparent base material. The antenna pattern is formed of a mesh-like conductor mesh layer. The antenna pattern includes a conductor portion serving as a formation portion of a non-transparent conductor layer, and a great number of openings serving as a non-formation portion.

### CITATION LIST

### Patent Literature

Patent Literature 1: Japanese Unexamined Patent Application Publication No. 2011-66610
Patent Literature 2: Japanese Patent No. 5636735
Patent Literature 3: Japanese Patent No. 5695947

The present embodiment provides an image display device laminate, an image display device, and a module, in which presence of a wiring board that is present in the image display device can be made to be less visually recognizable.

Also, in film antennas according to the related art, there are often cases in which the conductive mesh layer is fixed to another layer by using a transparent adhesive layer such as an OCA (Optical Clear Adhesive) or the like. The OCA is a flexible material, and accordingly it is difficult to maintain levelness between the conductive mesh layer and a ground layer. In this case, it is difficult to sufficiently improve antenna characteristics.

The present embodiment provides an image display device laminate and an image display device that are capable of improving antenna characteristics.

### SUMMARY OF INVENTION

A first aspect of the present disclosure is an image display device laminate including a wiring board that has a substrate including a first face and a second face situated on an opposite side from the first face, and a mesh wiring layer disposed on the first face of the substrate, a first adhesive layer situated on the first face side of the substrate, a second adhesive layer situated on the second face side of the substrate, and an intermediate layer situated in at least one of a position between the wiring board and the first adhesive layer and a position between the wiring board and the second adhesive layer. The substrate has transparency, and a partial region of the substrate is disposed in a partial region between the first adhesive layer and the second adhesive layer.

With a second aspect of the present disclosure, in the image display device laminate according to the above first aspect, the intermediate layer may be situated between the wiring board and the first adhesive layer, and also be situated between the wiring board and the second adhesive layer.

With a third aspect of the present disclosure, in the image display device laminate according to the above first aspect or the above second aspect, a thickness of the intermediate layer may be 1 μm or more and 50 μm or less.

With a fourth aspect of the present disclosure, in the image display device laminate according to each of the above first aspect to the above third aspect, a refractive index of the intermediate layer may be 1.40 or more and 1.60 or less.

With a fifth aspect of the present disclosure, in the image display device laminate according to each of the above first aspect to the above fourth aspect, a difference between a refractive index of the intermediate layer and a refractive index of the first adhesive layer may be 0.1 or less, a difference between the refractive index of the intermediate layer and a refractive index of the substrate may be 0.1 or less, and a difference between the refractive index of the intermediate layer and a refractive index of the second adhesive layer may be 0.1 or less.

With a sixth aspect of the present disclosure, in the image display device laminate according to each of the above first aspect to the above fifth aspect, a dielectric dissipation factor of the substrate may be 0.002 or less.

With a seventh aspect of the present disclosure, in the image display device laminate according to each of the above first aspect to the above sixth aspect, a relative permittivity of the substrate may be 2 or more and 10 or less.

With an eighth aspect of the present disclosure, in the image display device laminate according to each of the above first aspect to the above seventh aspect, the wiring board may have a radio wave transmission/reception function.

With a ninth aspect of the present disclosure, in the image display device laminate according to each of the above first aspect to the above eighth aspect, the wiring board may further have a power supply unit that is electrically connected to the mesh wiring layer, and the mesh wiring layer may include a transfer portion that is connected to the power supply unit and a transmission/reception unit that is connected to the transfer portion.

A tenth aspect of the present disclosure is an image display device including the image display device laminate according to any one of the above first aspect to the above ninth aspect, and a display device that is laminated on the image display device laminate.

An eleventh aspect of the present disclosure is an image display device laminate including a wiring board that has a substrate including a first face, a second face situated on an opposite side from the first face, and a third face situated between the first face and the second face, and a mesh wiring layer disposed on the first face of the substrate, a first adhesive layer situated on the first face side of the substrate, and a second adhesive layer situated on the second face side of the substrate. The substrate has transparency, a partial region of the substrate is disposed in a partial region between the first adhesive layer and the second adhesive layer, the third face of the substrate is covered by at least one of the first adhesive layer and the second adhesive layer, and a surface roughness Ra of the third face is 0.005 μm or more and 0.5 μm or less.

With a twelfth aspect of the present disclosure, in the image display device laminate according to the above eleventh aspect, a thickness of the substrate may be 2 μm or more and 50 μm or less.

With a thirteenth aspect of the present disclosure, in the image display device laminate according to the above eleventh aspect or the above twelfth aspect, a thickness of the first adhesive layer may be 1.5 times or more a thickness of the substrate, and may be 300 μm or less.

With a fourteenth aspect of the present disclosure, in the image display device laminate according to each of the above eleventh aspect to the above thirteenth aspect, a thickness of the second adhesive layer may be 1.5 times or more a thickness of the substrate, and may be 300 μm or less.

With a fifteenth aspect of the present disclosure, in the image display device laminate according to each of the above eleventh aspect to the above fourteenth aspect, the first adhesive layer and the second adhesive layer may each contain an acrylic-based resin.

With a sixteenth aspect of the present disclosure, in the image display device laminate according to each of the above eleventh aspect to the above fifteenth aspect, a dummy wiring layer that is electrically isolated from the mesh wiring layer may be provided on a periphery of the mesh wiring layer.

With a seventeenth aspect of the present disclosure, in the image display device laminate according to each of the above eleventh aspect to the above sixteenth aspect, a dielectric dissipation factor of the substrate may be 0.002 or less.

With an eighteenth aspect of the present disclosure, in the image display device laminate according to each of the above eleventh aspect to the above seventeenth aspect, a relative permittivity of the substrate may be 2 or more and 10 or less.

With a nineteenth aspect of the present disclosure, in the image display device laminate according to each of the above eleventh aspect to the above eighteenth aspect, the wiring board may have a radio wave transmission/reception function.

With a twentieth aspect of the present disclosure, in the image display device laminate according to each of the above eleventh aspect to the above nineteenth aspect, the wiring board may further have a power supply unit that is electrically connected to the mesh wiring layer, and the mesh wiring layer may include a transfer portion that is connected to the power supply unit, and a transmission/reception unit that is connected to the transfer portion.

A twenty-first aspect of the present disclosure is an image display device including the image display device laminate according to any one of the above eleventh aspect to the above twentieth aspect, and a display device that is laminated on the image display device laminate.

A twenty-second aspect of the present disclosure is a module including a wiring board that has a substrate including a first face, a second face situated on an opposite side from the first face, and a third face situated between the first face and the second face, a mesh wiring layer disposed on the first face of the substrate, and a power supply unit that is electrically connected to the mesh wiring layer, and a power supply line that is electrically connected to the power supply unit. A surface roughness Ra of the third face is 0.005 μm or more and 0.5 μm or less.

A twenty-third aspect of the present disclosure is an image display device laminate including a wiring board that has a substrate including a first face, a second face situated on an opposite side from the first face, and a third face situated between the first face and the second face, and a mesh wiring layer disposed on the first face of the substrate, a first adhesive layer situated on the first face side of the substrate, and a second adhesive layer situated on the second face side of the substrate. The substrate has transparency, a partial region of the substrate is disposed in a partial region between the first adhesive layer and the second adhesive layer, the third face of the substrate is covered by at least the first adhesive layer, and at least a part of the third face inclines to an outer side toward the second face from the first face.

With a twenty-fourth aspect of the present disclosure, in the image display device laminate according to the above twenty-third aspect, a length between a portion of the third face that is situated on an outermost side thereof, and a portion of the first face that is situated on an outermost side thereof, in a direction that is orthogonal to a direction normal to the first face, may be 0.15 times or more and 2 times or less a length between the portion of the third face that is situated on the outermost side thereof, and the portion of the first face that is situated on the outermost side thereof, in the direction normal to the first face.

With a twenty-fifth aspect of the present disclosure, in the image display device laminate according to the above twenty-third aspect and the above twenty-fourth aspect, a portion of the third face that is situated on an outermost side thereof may be between the first face and the second face in a cross-section taken in a direction normal to the first face, and a length between the portion of the third face that is situated on the outermost side thereof, and a portion of the second face that is situated on an outermost side thereof, in a direction that is orthogonal to the direction normal to the first face, may be 0.15 times or more and 2 times or less a length between the portion of the third face that is situated on the outermost side thereof, and the portion of the second face that is situated on the outermost side thereof, in the direction normal to the first face.

With a twenty-sixth aspect of the present disclosure, in the image display device laminate according to each of the above twenty-third aspect to the above twenty-fifth aspect, the third face may be curved in a cross-section taken in a direction normal to the first face.

With a twenty-seventh aspect of the present disclosure, in the image display device laminate according to each of the above twenty-third aspect to the above twenty-sixth aspect, the third face may head toward an outer side as the third face is closer to an interface between the first adhesive layer and the second adhesive layer, in a cross-section taken in a direction normal to the first face.

With a twenty-eighth aspect of the present disclosure, in the image display device laminate according to each of the above twenty-third aspect to the above twenty-seventh aspect, a thickness of the substrate may be 2 μm or more and 50 μm or less.

With a twenty-ninth aspect of the present disclosure, in the image display device laminate according to each of the above twenty-third aspect to the above twenty-eighth aspect, a thickness of the first adhesive layer may be 1.5 times or more a thickness of the substrate, and may be 300 μm or less.

With a thirtieth aspect of the present disclosure, in the image display device laminate according to each of the above twenty-third aspect to the above twenty-ninth aspect, a thickness of the second adhesive layer may be 1.5 times or more a thickness of the substrate, and may be 300 μm or less.

With a thirty-first aspect of the present disclosure, in the image display device laminate according to each of the above twenty-third aspect to the above thirtieth aspect, the first adhesive layer and the second adhesive layer may each contain an acrylic-based resin.

With a thirty-second aspect of the present disclosure, in the image display device laminate according to each of the above twenty-third aspect to the above thirty-first aspect, a thickness of the first adhesive layer may be more than a thickness of the second adhesive layer.

With a thirty-third aspect of the present disclosure, in the image display device laminate according to each of the above twenty-third aspect to the above thirty-second aspect, a difference between a thickness of the first adhesive layer and a thickness of the second adhesive layer may be 100 μm or less.

With a thirty-fourth aspect of the present disclosure, in the image display device laminate according to each of the above twenty-third aspect to the above thirty-third aspect, a dummy wiring layer that is electrically isolated from the mesh wiring layer may be provided on a periphery of the mesh wiring layer.

With a thirty-fifth aspect of the present disclosure, in the image display device laminate according to each of the above twenty-third aspect to the above thirty-fourth aspect, a dielectric dissipation factor of the substrate may be 0.002 or less.

With a thirty-sixth aspect of the present disclosure, in the image display device laminate according to each of the above twenty-third aspect to the above thirty-fifth aspect, a relative permittivity of the substrate may be 2 or more and 10 or less.

With a thirty-seventh aspect of the present disclosure, in the image display device laminate according to each of the above twenty-third aspect to the above thirty-sixth aspect, the wiring board may have a radio wave transmission/reception function.

With a thirty-eighth aspect of the present disclosure, in the image display device laminate according to each of the above twenty-third aspect to the above thirty-seventh aspect, the wiring board may further have a power supply unit that is electrically connected to the mesh wiring layer, and the mesh wiring layer may include a transfer portion that is connected to the power supply unit, and a transmission/reception unit that is connected to the transfer portion.

A thirty-fifth aspect of the present disclosure is an image display device including the image display device laminate according to any one of the above twentieth aspect to the above thirty-fourth aspect, and a display device that is laminated on the image display device laminate.

A fortieth aspect of the present disclosure is a module including a wiring board that has a substrate, including a first face, a second face situated on an opposite side from the first face, and a third face situated between the first face and the second face, a mesh wiring layer disposed on the first face of the substrate and a power supply unit that is electrically connected to the mesh wiring layer, and a power supply line that is electrically connected to the power supply unit. At least a part of the third face inclines to an outer side toward the second face from the first face.

A forty-first aspect of the present disclosure is an image display device laminate including a substrate, a mesh wiring layer disposed on the substrate, a conductive layer, and an adhesive layer that is situated between the conductive layer and the substrate. The substrate has transparency, the adhesive layer has transparency, and L_{zmin}≥0.9 L_{zmax} holds, where L_{zmin} is a shortest distance between the mesh wiring layer and the conductive layer in a direction normal to the conductive layer and L_{zmax} is a longest distance between the mesh wiring layer and the conductive layer in the direction normal to the conductive layer. To have transparency as used here means that transmittance of rays of light of wavelengths of 400 nm or higher and 700 nm or lower is 85% or less.

With a forty-second aspect of the present disclosure, in the image display device laminate according to the above forty-first aspect, a storage elastic modulus of the adhesive layer at 25° C. may be 1×10⁴ Pa or more.

With a forty-third aspect of the present disclosure, in the image display device laminate according to the above forty-first aspect or the above forty-second aspect, T₁ₘᵢₙ≥0.9 T₁ₘₐₓ may hold, where T₁ₘₐₓ is an in-plane greatest thickness of the substrate and T₁ₘᵢₙ is an in-plane smallest thickness of the substrate.

With a forty-fourth aspect of the present disclosure, in the image display device laminate according to each of the above forty-first aspect to the above forty-third aspect, T₂ₘᵢₙ≥0.9 T₂ₘₐₓ may hold, where T₂ₘₐₓ is an in-plane greatest thickness of the adhesive layer and T₂ₘᵢₙ is an in-plane smallest thickness of the adhesive layer.

A forty-fifth aspect of the present disclosure is an image display device including the image display device laminate according to each of the above forty-first aspect to the above forty-fourth aspect, and a display device that is laminated on the image display device laminate.

According to an embodiment of the present disclosure, the presence of the wiring board that is present in the image display device can be made to be less visually recognizable.

Also, according to an embodiment of the present disclosure, antenna characteristics can be improved.

### BRIEF DESCRIPTION OF DRAWINGS

FIG. 1 is a plan view illustrating an image display device according to a first embodiment.

FIG. 2 is a sectional view (sectional view along line II-II in FIG. 1) illustrating the image display device according to the first embodiment.

FIG. 3 is a plan view illustrating a wiring board.

FIG. 4 is an enlarged plan view illustrating a mesh wiring layer of the wiring board.

FIG. 5 is a sectional view (sectional view along line V-V in FIG. 4) illustrating the wiring board.

FIG. 6 is a sectional view (sectional view along line VI-VI in FIG. 4) illustrating the wiring board.

FIGS. 7(a) to 7(f) are sectional views illustrating a manufacturing method of an image display device laminate according to the first embodiment.

FIGS. 8(a) to 8(c) are sectional views illustrating a manufacturing method of the image display device laminate according to the first embodiment.

FIG. 9 is a sectional view illustrating the image display device laminate according to a first modification.

FIG. 10 is a sectional view illustrating an image display device laminate according to a second modification.

FIG. 11 is a sectional view illustrating an image display device laminate according to a third modification.

FIG. 12 is a plan view illustrating a wiring board according to a first modification.

FIG. 13 is an enlarged plan view illustrating the wiring board according to the first modification.

FIG. 14 is a plan view illustrating the wiring board according to a second modification.

FIG. 15 is an enlarged plan view illustrating the wiring board according to the second modification.

FIG. 16 is an enlarged plan view illustrating a mesh wiring layer of a wiring board according to a third modification.

FIG. 17 is a plan view illustrating an image display device according to a second embodiment.

FIG. 18 is a sectional view (sectional view along line XVIII-XVIII in FIG. 17) illustrating the image display device according to the second embodiment.

FIGS. 19(a) to 19(c) are sectional views illustrating a manufacturing method of an image display device laminate according to the second embodiment.

FIG. 20 is a diagram for describing a visibility evaluation test according to an Example.

FIG. 21 is a diagram for describing the visibility evaluation test according to the Example.

FIG. 22 is a sectional view illustrating an image display device according to a third embodiment (sectional view corresponding to FIG. 2).

FIG. 23 is a sectional view illustrating the image display device according to the third embodiment (enlarged view of portion XXIII in FIG. 22).

FIGS. 24(a) to 24(c) are sectional views illustrating a manufacturing method of the image display device laminate according to the third embodiment.

FIG. 25 is a sectional view illustrating an image display device laminate according to a first modification (sectional view corresponding to FIG. 23).

FIG. 26 is a sectional view illustrating an image display device laminate according to a second modification (sectional view corresponding to FIG. 23).

FIG. 27 is a sectional view illustrating an image display device laminate according to a third modification (sectional view corresponding to FIG. 23).

FIG. 28 is a sectional view illustrating an image display device laminate according to a fourth modification (sectional view corresponding to FIG. 23).

FIG. 29 is a sectional view illustrating an image display device laminate according to a fifth modification (sectional view corresponding to FIG. 23).

FIG. 30 is a sectional view illustrating an image display device laminate according to a sixth modification (sectional view corresponding to FIG. 23).

FIG. 31 is a sectional view illustrating an image display device laminate according to a seventh modification (sectional view corresponding to FIG. 23).

FIG. 32 is a sectional view illustrating an image display device laminate according to an eighth modification (sectional view corresponding to FIG. 23).

FIG. 33 is a schematic exploded perspective view illustrating an image display device according to a fourth embodiment.

FIG. 34 is a sectional view illustrating the image display device according to the fourth embodiment (sectional view corresponding to FIG. 2).

FIG. 35 is a sectional view illustrating the image display device according to the fourth embodiment.

### DESCRIPTION OF EMBODIMENTS

### First Embodiment

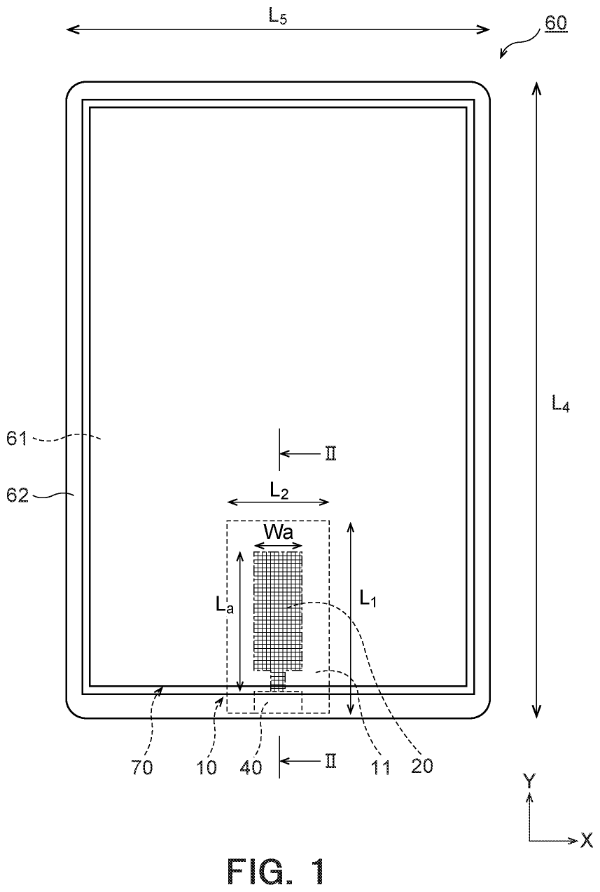

First, a first embodiment will be described by way of FIG. 1 to FIG. 8. FIG. 1 to FIG. 8 are diagrams illustrating the present embodiment.

The diagrams described below are schematically illustrated diagrams. Accordingly, sizes and shapes of each of the portions are exaggerated as appropriate, in order to facilitate understanding. Also, implementation can be carried out modified as appropriate without departing from the technical spirit. Note that in the diagrams described below, parts that are the same are denoted by the same signs, and detailed description may be partly omitted. Also, numerical values, such as dimensions and so forth, and names of materials of the members described in the present specification are exemplary as embodiments, and can be selected as appropriate and used without being limited thereto. In the present specification, terms that identify shapes or geometrical conditions, such as for example, the terms parallel, orthogonal, perpendicular, and so forth, can be interpreted including, in addition to strict meanings thereof, states that are substantially the same.

Also, in the embodiment below, “X direction” is a direction parallel to one side of an image display device. “Y direction” is a direction that is perpendicular to the X direction and also parallel to the other side of the image display device. “Z direction” is a direction that is perpendicular to both the X direction and the Y direction, and is parallel to a thickness direction of the image display device. Also, “front face” is a face on a plus side in the Z direction, which is a light-emitting face side of the image display device, and is a face that faces the observer side. “Rear face” is a face on a minus side in the Z direction, which is a face opposite to the light-emitting face of the image display device and to the face that faces the observer side. Note that in the present embodiment, an example will be described in which a mesh wiring layer 20 is a mesh wiring layer 20 having radio wave transmission/reception functions (functions as an antenna), but the mesh wiring layer 20 does not have to have such radio wave transmission/reception functions (functions as an antenna).

### [Configuration of Image Display Device]

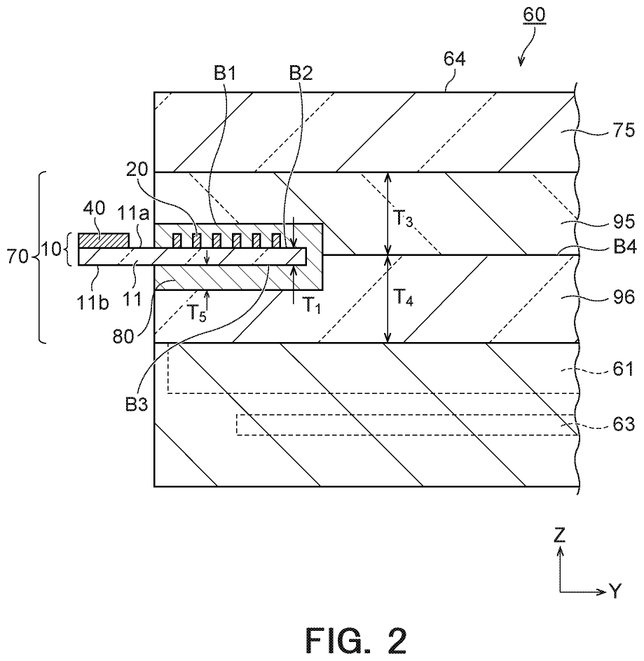

A configuration of the image display device according to the present embodiment will be described with reference to FIG. 1 and FIG. 2.

As illustrated in FIG. 1 and FIG. 2, an image display device 60 according to the present embodiment includes an image display device laminate 70, and a display device (display) 61 that is laminated on the image display device laminate 70. Of these, the image display device laminate 70 includes a first transparent adhesive layer (first adhesive layer) 95, a second transparent adhesive layer (second adhesive layer) 96, a wiring board 10, and an intermediate layer 80. Of these, the wiring board 10 has a substrate 11 including a first face 11a and a second face 11b situated on an opposite side from the first face 11a, and the mesh wiring layer 20 disposed on the first face 11a of the substrate 11. Also, the wiring board 10 may further have a power supply unit 40 that is electrically connected to the mesh wiring layer 20. Also, a communication module 63 is disposed on the minus side of the display device 61 in the Z direction. The image display device laminate 70, the display device 61, and the communication module 63 are accommodated in a housing 62.

In the image display device 60 illustrated in FIG. 1 and FIG. 2, radio waves of a predetermined frequency can be transmitted/received, and communication can be performed via the communication module 63. The communication module 63 may include one of an antenna for telephone, an antenna for WiFi, an antenna for 3G, an antenna for 4G, an antenna for 5G, an antenna for LTE, an antenna for Bluetooth (registered trademark), an antenna for NFC, and so forth. Examples of such image display devices 60 include mobile terminal equipment such as smartphones, tablets, and so forth.

As illustrated in FIG. 2, the image display device 60 has a light-emitting face 64. The image display device 60 includes the wiring board 10 that is situated on the light-emitting face 64 side (plus side in Z direction) as to the display device 61, and the communication module 63 that is situated on the opposite side from the light-emitting face 64 (minus side in Z direction) as to the display device 61.

The display device 61 is made up of an organic EL (Electro Luminescence) display device, for example. The display device 61 may include a metal layer, a support base material, a resin base material, a thin-film transistor (TFT), and an organic EL layer, which are not illustrated, for example. A touch sensor that is not illustrated may be disposed over the display device 61. Also, the wiring board 10 is disposed over the display device 61 with the second transparent adhesive layer 96 interposed therebetween. Note that the display device 61 is not limited to an organic EL display device. For example, the display device 61 may be another display device that has functions of light emission in itself, and may be a micro-LED display device including microscopic LED elements (light emitters). Alternatively, the display device 61 may be a liquid crystal display device including liquid crystal. Also, a cover glass (surface protective plate) 75 is disposed over the wiring board 10 with the first transparent adhesive layer 95 interposed therebetween. Note that a decorative film and a polarizing plate, which are not illustrated, may be disposed between the first transparent adhesive layer 95 and the cover glass 75.

The first transparent adhesive layer 95 is an adhesive layer that directly or indirectly bonds the wiring board 10 to the cover glass 75. This first transparent adhesive layer 95 is situated on the first face 11a side of the substrate 11. The first transparent adhesive layer 95 has optical transparency, and may be an OCA (Optical Clear Adhesive) layer. The OCA layer is a layer that is fabricated as follows, for example. First, a curable adhesive layer composition that is in a liquid state and that includes a polymerizable compound is coated on a releasing film of polyethylene terephthalate (PET) or the like, and then cured by using ultraviolet rays (UV) or the like, for example, thereby obtaining an OCA sheet. This OCA sheet is applied to an object, following which the releasing film is removed by separation, thereby obtaining the OCA layer. The material of the first transparent adhesive layer 95 may be an acrylic-based resin, a silicone-based resin, a urethane-based resin, or the like. In particular, the first transparent adhesive layer 95 may contain an acrylic-based resin. In this case, the second transparent adhesive layer 96 preferably contains acrylic-based resin. This substantially does away with difference in refractive index between the first transparent adhesive layer 95 and the second transparent adhesive layer 96, and reflection of visible light at an interface B4 between the first transparent adhesive layer 95 and the second transparent adhesive layer 96 can be suppressed in a more reliable manner.

Also, the transmittance of visible light rays (light rays of wavelengths 400 nm or more and 700 nm or less) of the first transparent adhesive layer 95 may be 85% or more, and preferably is 90% or more. Note that there is no upper limit in particular to the transmittance of visible light rays of the first transparent adhesive layer 95, but this may be, for example, 100% or less. Making the transmittance of visible light rays of the first transparent adhesive layer 95 to be in the above range raises the transparency of the image display device laminate 70, thereby facilitating visibility of the display device 61 of the image display device 60.

The wiring board 10 is disposed on the light-emitting face 64 side from the display device 61, as described above. In this case, the wiring board 10 is situated between the first transparent adhesive layer 95 and the second transparent adhesive layer 96. More specifically, a partial region of the substrate 11 of the wiring board 10 is disposed in a partial region between the first transparent adhesive layer 95 and the second transparent adhesive layer 96. In this case, the first transparent adhesive layer 95, the second transparent adhesive layer 96, the display device 61, and the cover glass 75 each have a greater area than that of the substrate 11 of the wiring board 10. Thus, disposing the substrate 11 of the wiring board 10 in not the entire area of the image display device 60 in plan view but in a partial region thereof enables the overall thickness of the image display device 60 to be reduced.

The wiring board 10 has the substrate 11 that has transparency, and the mesh wiring layer 20 disposed on the first face 11a of the substrate 11. The power supply unit 40 is electrically connected to the mesh wiring layer 20. The power supply unit 40 is electrically connected to the communication module 63. Also, part of the wiring board 10 is not disposed between the first transparent adhesive layer 95 and the second transparent adhesive layer 96, but protrudes to an outer side (minus side in Y direction) from between the first transparent adhesive layer 95 and the second transparent adhesive layer 96. Specifically, a region of the wiring board 10 in which the power supply unit 40 is provided protrudes to the outer side. Accordingly, electrical connection between the power supply unit 40 and the communication module 63 is facilitated. On the other hand, a region of the wiring board 10 in which the mesh wiring layer 20 is provided is situated between the first transparent adhesive layer 95 and the second transparent adhesive layer 96. Note that details of the wiring board 10 will be described later.

The second transparent adhesive layer 96 is an adhesive layer that directly or indirectly bonds the display device 61 to the wiring board 10. The second transparent adhesive layer 96 is situated on the second face 11b side of the substrate 11. The second transparent adhesive layer 96 has optical transparency, and may be an OCA (Optical Clear Adhesive) layer, in the same way as the first transparent adhesive layer 95. The material of the second transparent adhesive layer 96 may be an acrylic-based resin, a silicone-based resin, a urethane-based resin, or the like. In particular, the second transparent adhesive layer 96 may contain an acrylic-based resin. This substantially does away with difference in refractive index between the first transparent adhesive layer 95 and the second transparent adhesive layer 96, and reflection of visible light at the interface B4 between the first transparent adhesive layer 95 and the second transparent adhesive layer 96 can be suppressed in a more reliable manner.

Also, the transmittance of visible light rays (light rays of wavelengths 400 nm or more and 700 nm or less) of the second transparent adhesive layer 96 may be 85% or more, and preferably is 90% or more. Note that there is no upper limit in particular to the transmittance of visible light rays of the second transparent adhesive layer 96, but this may be, for example, 100% or less. Making the transmittance of visible light rays of the second transparent adhesive layer 96 to be in the above range raises the transparency of the image display device laminate 70, thereby facilitating visibility of the display device 61 of the image display device 60.

In this image display device laminate 70, the difference between the refractive index of the first transparent adhesive layer 95 and the refractive index of the second transparent adhesive layer 96 is preferably 0.1 or less, and more preferably is 0.05 or less. Thus, reflection of visible light at the interface B4 between the first transparent adhesive layer 95 and the second transparent adhesive layer 96 can be suppressed, and the first transparent adhesive layer 95 and the second transparent adhesive layer 96 can be made to be less visually recognizable by the bare eye of an observer. For example, in a case in which the material of the first transparent adhesive layer 95 is an acrylic-based resin (refractive index 1.49), the refractive index of the second transparent adhesive layer 96 is 1.39 or more and 1.59 or less. Refractive index here refers to absolute refractive index, and can be found on the basis of Method A of JIS K-7142.

In particular, the material of the first transparent adhesive layer 95 and the material of the second transparent adhesive layer 96 is preferably the same material as each other. Accordingly, the difference in the refractive indices between the first transparent adhesive layer 95 and the second transparent adhesive layer 96 can be further reduced, and reflection of visible light at the interface B4 between the first transparent adhesive layer 95 and the second transparent adhesive layer 96 can be suppressed.

Also, in FIG. 2, at least one thickness of thickness T₃ of the first transparent adhesive layer 95 and thickness T₄ of the second transparent adhesive layer 96 may be 1.5 times the thickness T₁ of the substrate 11 or more, preferably is 2 times thereof or more, and even more preferably is 2.5 times thereof or more. By making the thickness T₃ of the first transparent adhesive layer 95 or the thickness T₄ of the second transparent adhesive layer 96 to be sufficiently thick as to the thickness T₁ of the substrate 11 in this way, the first transparent adhesive layer 95 or the second transparent adhesive layer 96 deforms in the thickness direction in a region overlapping the substrate 11, and takes up the thickness of the substrate 11. Accordingly, stepped portions can be suppressed from being formed in the first transparent adhesive layer 95 or the second transparent adhesive layer 96 at a peripheral edge of the substrate 11, and the presence of the substrate 11 can be made to be less visually recognizable by the observer.

Also, at least one thickness of the thickness T₃ of the first transparent adhesive layer 95 and the thickness T₄ of the second transparent adhesive layer 96 may be 10 times the thickness T₁ of the substrate 11 or less, and preferably is five times thereof or less. Accordingly, the thickness T₃ of the first transparent adhesive layer 95 or the thickness T₄ of the second transparent adhesive layer 96 does not become too great, and the thickness of the overall image display device 60 can be reduced.

Also, in FIG. 2, the thickness T₃ of the first transparent adhesive layer 95 may be greater than the thickness T₄ of the second transparent adhesive layer 96. As described earlier, the first transparent adhesive layer 95 is situated on the first face 11a side of the substrate 11 of the wiring board 10. Also, the mesh wiring layer 20 is disposed on the first face 11a of the substrate 11 of the wiring board 10. Accordingly, there is a possibility of unevenness being formed on the surface of the first transparent adhesive layer 95 due to unevenness formed by the mesh wiring layer 20. Conversely, unevenness can be suppressed from being formed on the surface of the first transparent adhesive layer 95 due to the thickness T₃ of the first transparent adhesive layer 95 being greater than the thickness T₄ of the second transparent adhesive layer 96, and accordingly the surface of the first transparent adhesive layer 95 can be made to be smooth.

The difference between the thickness T₃ of the first transparent adhesive layer 95 and the thickness T₄ of the second transparent adhesive layer 96 preferably is 100 μm or less. As described earlier, the first transparent adhesive layer 95 and the second transparent adhesive layer 96 can be OCA layers. Accordingly, residual stress that can be generated in the OCA layers at the time of fabricating the OCA layers can generate tensile stress that acts on the first transparent adhesive layer 95 and the second transparent adhesive layer 96 so as to contract the first transparent adhesive layer 95 and the second transparent adhesive layer 96. There is a possibility that this tensile stress will increase as the thickness T₃ of the first transparent adhesive layer 95 or the thickness T₄ of the second transparent adhesive layer 96 increases. In a case in which the difference between the tensile stress generated in the first transparent adhesive layer 95 and the tensile stress generated in the second transparent adhesive layer 96 becomes great, there is a possibility of warpage occurring in the wiring board 10. Conversely, due to the difference between the thickness T₃ of the first transparent adhesive layer 95 and the thickness T₄ of the second transparent adhesive layer 96 being 100 μm or less, the difference between the tensile stress generated in the first transparent adhesive layer 95 and the tensile stress generated in the second transparent adhesive layer 96 can be reduced. Accordingly, warpage of the wiring board 10 due to the difference between the tensile stress generated in the first transparent adhesive layer 95 and the tensile stress generated in the second transparent adhesive layer 96 can be reduced.

Also, in FIG. 2, the thickness T₃ of the first transparent adhesive layer 95 and the thickness T₄ of the second transparent adhesive layer 96 may be the same as each other. In this case, the thickness T₃ of the first transparent adhesive layer 95 and the thickness T₄ of the second transparent adhesive layer 96 may each be 1.5 times the thickness T₁ of the substrate 11 or more, and preferably 2.0 times thereof or more. That is to say, the total of the thickness T₃ of the first transparent adhesive layer 95 and the thickness T₄ of the second transparent adhesive layer 96 (T₃+T₄) is three times the thickness T₁ of the substrate 11 or more. Thus, by making the total of thicknesses T₃ and T₄ of the first transparent adhesive layer 95 and the second transparent adhesive layer 96 to be sufficiently thick with respect to the thickness T₁ of the substrate 11, the first transparent adhesive layer 95 and the second transparent adhesive layer 96 deform (contract) in the thickness direction in the region overlapping the substrate 11, and take up the thickness of the substrate 11. Accordingly, stepped portions can be suppressed from being formed in the first transparent adhesive layer 95 or the second transparent adhesive layer 96 at the peripheral edge of the substrate 11, and the presence of the substrate 11 can be made to be less visually recognizable by the observer.

Also, in a case in which the thickness T₃ of the first transparent adhesive layer 95 and the thickness T₄ of the second transparent adhesive layer 96 are the same as each other, the thickness T₃ of the first transparent adhesive layer 95 and the thickness T₄ of the second transparent adhesive layer 96 may each be five times the thickness T₁ of the substrate 11 or less, and preferably three times thereof or less. Accordingly, the thicknesses T₃ and T₄ of both of the first transparent adhesive layer 95 and the second transparent adhesive layer 96 do not become too great, and the thickness of the overall image display device 60 can be reduced.

Specifically, the thickness T₁ of the substrate 11 may be 1 μm or more and 200 μm or less for example, may be 2 μm or more and 200 μm or less, may be 5 μm or more and 50 μm or less, may be 2 μm or more and 50 μm or less, may be 10 μm or more and 50 μm or less, and preferably is 15 μm or more and 25 μm or less. By making the thickness T₁ of the substrate 11 to be 1 μm or more, strength of the wiring board 10 can be maintained, so that a first-direction wiring line 21 and a second-direction wiring line 22 of the mesh wiring layer 20, which will be described later, are less likely to be deformed. By making the thickness T₁ of the substrate 11 to be 200 μm or less, stepped portions can be suppressed from being formed between the first transparent adhesive layer 95 and the second transparent adhesive layer 96 at the peripheral edge of the substrate 11, and the presence of the substrate 11 can be less recognizable by the observer. Also, by making the thickness T₁ of the substrate 11 to be 50 μm or less, stepped portions can be further suppressed from being formed in the first transparent adhesive layer 95 and the second transparent adhesive layer 96 at the peripheral edge of the substrate 11, and the presence of the substrate 11 can be made to be even more less visually recognizable by the observer.

The thickness T₃ of the first transparent adhesive layer 95 may be 1 μm or more and 500 μm or less for example, may be 15 μm or more and 500 μm or less, may be 15 μm or more and 300 μm or less, may be 20 μm or more and 250 μm or less, and preferably is 10 μm or more and 250 μm or less. Due to the thickness T₃ of the first transparent adhesive layer 95 being 500 μm or less, the thickness T₃ of the first transparent adhesive layer 95 does not become too great, and the overall thickness of the image display device 60 can be made to be thinner. Also, due to the thickness T₃ of the first transparent adhesive layer 95 being 300 μm or less, the overall thickness of the image display device 60 can be made to be even thinner.

The thickness T₄ of the second transparent adhesive layer 96 may be 1 μm or more and 500 μm or less for example, may be 15 μm or more and 500 μm or less, may be 15 μm or more and 300 μm or less, may be 20 μm or more and 250 μm or less, and preferably is 10 μm or more and 250 μm or less. Due to the thickness T₄ of the second transparent adhesive layer 96 being 500 μm or less, the thickness T₄ of the second transparent adhesive layer 96 does not become too great, and the overall thickness of the image display device 60 can be made to be thinner. Also, due to the thickness T₄ of the second transparent adhesive layer 96 being 300 μm or less, the overall thickness of the image display device 60 can be made to be even thinner.

As described earlier, the image display device laminate 70 includes the intermediate layer 80. The intermediate layer 80 is situated between the wiring board 10 and the first transparent adhesive layer 95, and also is situated between the wiring board 10 and the second transparent adhesive layer 96. Thus, the wiring board 10 can be made to be less visually recognizable by the bare eye of the observer, due to the image display device laminate 70 including the intermediate layer 80. In the present embodiment, the wiring board 10 is covered by the intermediate layer 80.

A thickness T₅ of the intermediate layer 80 is preferably 1 μm or more and 50 μm or less. Due to the thickness T₅ of the intermediate layer 80 being 1 μm or more, the wiring board 10 can be made to be further less visually recognizable by the bare eye of the observer. Also, due to the thickness T₅ of the intermediate layer 80 being 50 μm or less, the thickness T₅ of the intermediate layer 80 does not become too great, and the overall thickness of the image display device 60 can be made to be thinner. Note that in the present specification, “thickness of the intermediate layer” refers to a distance from the first face 11a of the substrate 11 to a face of the intermediate layer 80 faces on a plus side thereof in the Z direction, or to a distance from the second face 11b of the substrate 11 to a face of the intermediate layer 80 faces on a minus side thereof in the Z direction.

The refractive index of the intermediate layer 80 preferably is 1.40 or more and 1.60 or less, and more preferably is 1.45 or more and 1.55 or less. Due to the refractive index of the intermediate layer 80 being 1.40 or more and 1.60 or less, the difference between the refractive index of the intermediate layer 80 and the refractive index of the first transparent adhesive layer 95, the refractive index of the second transparent adhesive layer 96, or the refractive index of the substrate 11 can be made to be small.

The difference between the refractive index of the intermediate layer 80 and the refractive index of the first transparent adhesive layer 95 is preferably 0.1 or less. Also, the difference between the refractive index of the intermediate layer 80 and the refractive index of the substrate 11 is preferably 0.1 or less. Further, the difference between the refractive index of the intermediate layer 80 and the refractive index of the second transparent adhesive layer 96 is preferably 0.1 or less.

Thus, by suppressing the difference in the refractive index of the intermediate layer 80 and the refractive index of the first transparent adhesive layer 95 to 0.1 or less, reflection of visible light at an interface B1 between the intermediate layer 80 and the first transparent adhesive layer 95 can be suppressed, and the substrate 11 can be made to be less visually recognizable by the bare eye of the observer. Also, by suppressing the difference in the refractive index of the intermediate layer 80 and the refractive index of the substrate 11 to 0.1 or less, reflection of visible light at an interface B2 between the intermediate layer 80 and the substrate 11 can be suppressed, and the substrate 11 can be made to be less visually recognizable by the bare eye of the observer. Further, by suppressing the difference in the refractive index of the intermediate layer 80 and the refractive index of the second transparent adhesive layer 96 to 0.1 or less, reflection of visible light at an interface B3 between the intermediate layer 80 and the second transparent adhesive layer 96 can be suppressed, and the substrate 11 can be made to be less visually recognizable by the bare eye of the observer.

As described above, the image display device laminate 70 is made up of the wiring board 10, the intermediate layer 80, the first transparent adhesive layer 95 that has a greater area than that of the substrate 11 of the wiring board 10, and the second transparent adhesive layer 96 that has a greater area than that of the substrate 11. Such an image display device laminate 70 is also provided in the present embodiment.

The cover glass (surface protective plate) 75 is directly or indirectly disposed on the first transparent adhesive layer 95. This cover glass 75 is a member made of glass that transmits light (visible light). The transmittance of visible light rays of the cover glass 75 may be 85% or more, and preferably is 90% or more. Although there is no upper limit in particular regarding the transmittance of visible light rays of the cover glass 75, this may be 100% or less, for example. The cover glass 75 is plate-like, and may have a rectangular shape in plan view. The thickness of the cover glass 75 may be 200 μm or more and 1000 μm or less for example, and preferably is 300 μm or more and 700 μm or less. The length of the cover glass 75 in a longitudinal direction (Y direction) may be 20 mm or more and 500 mm or less for example, and preferably 100 mm or more and 200 mm or less, and the length of the cover glass 75 in the lateral direction (X direction) may be 20 mm or more and 500 mm or less, and preferably 50 mm or more and 100 mm or less. The planar shape of the cover glass 75 may be larger than the planar shapes of the wiring board 10 and the display device 61.

As illustrated in FIG. 1, the image display device 60 is substantially rectangular overall in plan view, the longitudinal direction thereof is parallel to the Y direction, and the lateral direction thereof is parallel to the X direction. A length L₄ of the image display device 60 in the longitudinal direction (Y direction) can be selected from a range of 20 mm or more and 500 mm or less for example, and preferably 100 mm or more and 200 mm or less. A length L₅ of the image display device 60 in the lateral direction (X direction) can be selected from a range of 20 mm or more and 500 mm or less for example, and preferably 50 mm or more and 100 mm or less. Note that corner portions of the image display device 60 each may be rounded.

### [Configuration of Wiring Board]

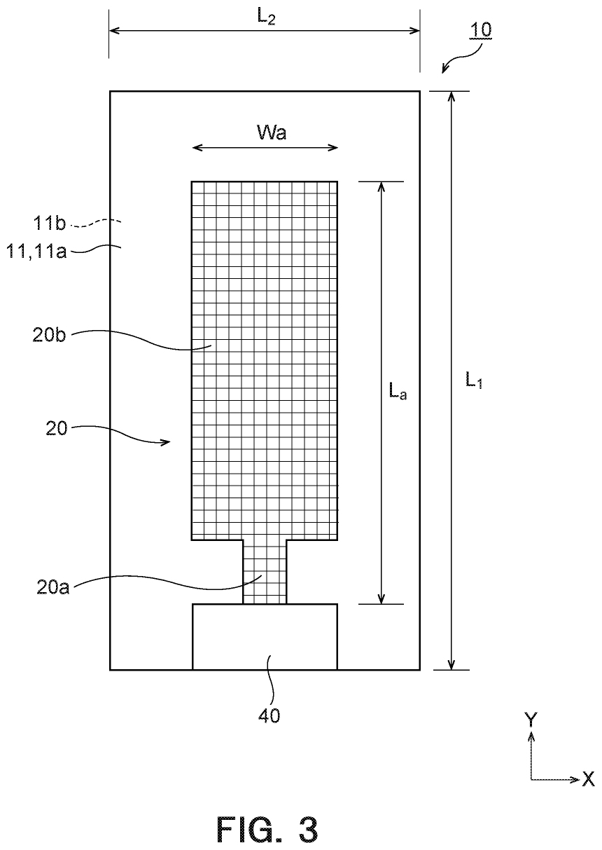

Next, a configuration of the wiring board will be described with reference to FIG. 3 to FIG. 6. FIG. 3 to FIG. 6 are diagrams illustrating the wiring board according to the present embodiment.

As illustrated in FIG. 3, the wiring board 10 according to the present embodiment is used in the image display device 60 (see FIG. 1 and FIG. 2) described above, and is disposed between the first transparent adhesive layer 95 and the second transparent adhesive layer 96, closer to the light-emitting face 64 side than the display device 61. Such a wiring board 10 includes the substrate 11 that has transparency, and the mesh wiring layer 20 disposed on the substrate 11. Also, the power supply unit 40 is electrically connected to the mesh wiring layer 20.

Of these, the substrate 11 has a substantially rectangular shape in plan view, with a longitudinal direction thereof being parallel to the Y direction, and a lateral direction thereof being parallel to the X direction. The substrate 11 has transparency and also has a substantially plate-like shape, and a thickness thereof is substantially uniform overall. A length L₁ of the substrate 11 in the longitudinal direction (Y direction) can be selected from a range of 2 mm or more and 300 mm or less, a range of 10 mm or more and 200 mm or less, or a range of 100 mm or more and 200 mm or less, for example. A length L₂ of the substrate 11 in the lateral direction (X direction) can be selected from a range of 2 mm or more and 300 mm or less, a range of 3 mm or more and 100 mm or less, or a range of 50 mm or more and 100 mm or less, for example. Note that corner portions of the substrate 11 may each be rounded.

It is sufficient for material of the substrate 11 to be a material that has transparency in the visible light domain, and electrical insulating properties. A polyester-based resin such as polyethylene terephthalate or the like, an acrylic-based resin such as polymethyl methacrylate, a polycarbonate-based resin, a polyimide-based resin, or a polyolefin-based resin such as a cycloolefin polymer, a cellulose-based resin such as triacetyl cellulose or the like, a fluororesin material such as PTFE, PFA, and so forth, and like organic insulating materials, for example, is preferably used as the material of the substrate 11. Alternatively, an organic insulating material such as a cycloolefin polymer (e.g., ZF-16 manufactured by Zeon Corporation), a polynorbornene polymer (manufactured by Sumitomo Bakelite Co. Ltd.), or the like may be used as the material of the substrate 11. Also, depending on the usage, glass, ceramics, and so forth can be selected as appropriate as the material of the substrate 11. Note that an example is illustrated in which the substrate 11 is made up of a single layer, but this is not restrictive, and a structure may be made in which a plurality of base materials or layers are laminated. Also, the substrate 11 may be film-like or may be plate-like.

Also, the dielectric dissipation factor of the substrate 11 may be 0.002 or less, and preferably is 0.001 or less. Note that while there is no particular lower limit, the dielectric dissipation factor of the substrate 11 may be greater than 0. Having the dielectric dissipation factor of the substrate 11 in the above range enables loss of gain (sensitivity) in conjunction with transmission/reception of electromagnetic waves to be reduced, particularly in a case in which the electromagnetic waves transmitted/received by the mesh wiring layer 20 (e.g., millimeter waves) are radio frequency waves. Note that the lower limit of the dielectric dissipation factor of the substrate 11 is not limited in particular.

The relative permittivity of the substrate 11 preferably is 2 or more and 10 or less. A greater range of options is available as the material of the substrate 11 by the relative permittivity of the substrate 11 being 2 or more. Also, loss of gain (sensitivity) in conjunction with transmission/reception of electromagnetic waves can be reduced by the relative permittivity of the substrate 11 being 10 or less. That is to say, in a case in which the relative permittivity of the substrate 11 is great, the effects of the thickness of the substrate 11 on propagation of electromagnetic waves increases. Also, in a case in having adverse effects on the propagation of electromagnetic waves, the dielectric dissipation factor of the substrate 11 increases, and loss of gain (sensitivity) in conjunction with transmission/reception of electromagnetic waves can increase. Conversely, the relative permittivity of the substrate 11 being 10 or less can reduce the effects of the thickness of the substrate 11 on the propagation of electromagnetic waves. Accordingly, loss of gain (sensitivity) in conjunction with transmission/reception of electromagnetic waves can be reduced. In particular, in a case in which the electromagnetic waves transmitted/received by the mesh wiring layer 20 (e.g., millimeter waves) are radio frequency waves, loss of gain (sensitivity) in conjunction with transmission/reception of electromagnetic waves can be reduced.

The dielectric dissipation factor and the relative permittivity of the substrate 11 can be measured in conformance with IEC 62562. Specifically, first, a portion of the substrate 11 on which the mesh wiring layer 20 is not formed is cut out to prepare a test piece. The dimensions of the test piece are 10 mm to 20 mm in width and 50 mm to 100 mm in length. Next, the dielectric dissipation factor or the relative permittivity is measured in conformance with IEC 62562.

Also, the substrate 11 has transparency. In the present specification, “has transparency” means transmittance of visible light rays (light rays having wavelength of 400 nm or higher and 700 nm or lower) being 85% or more. The transmittance of the substrate 11 regarding visible light rays (light rays having wavelength of 400 nm or higher and 700 nm or lower) may be 85% or more, and preferably is 90% or more. There is no upper limit to the transmittance of visible light rays of the substrate 11 in particular, but may be 100% or less, for example. Having the transmittance of visible light rays of the substrate 11 in the above range increases the transparency of the wiring board 10, and facilitates visual recognition of the display device 61 of the image display device 60. Note that the term visible light rays refers to light rays having a wavelength of 400 nm or higher and 700 nm or lower. Also, the term transmittance of visible light rays of 85% or more means that transmittance of the entire wavelength domain of 400 nm or higher and 700 nm or lower is 85% or more when light absorbance is measured for the substrate 11 using a known spectrophotometer (e.g., spectroscope: V-670 manufactured by JASCO Corporation).

In the present embodiment, the mesh wiring layer 20 is made up of an antenna pattern having functions as an antenna. In FIG. 3, one mesh wiring layer 20 is formed on the substrate 11. Also, as illustrated in FIG. 3, the mesh wiring layer 20 may be present only on a partial region of the substrate 11, rather than being present over the entire face of the substrate 11. This mesh wiring layer 20 corresponds to a predetermined frequency band. That is to say, the length (length in Y direction) Lₐ of the mesh wiring layer 20 has a length corresponding to a particular frequency band. Note that the lower frequency the corresponding frequency band is, the longer a length Lₐ of the mesh wiring layer 20 becomes. The mesh wiring layer 20 may correspond to one of an antenna for telephone, an antenna for WiFi, an antenna for 3G, an antenna for 4G, an antenna for 5G, an antenna for LTE, an antenna for Bluetooth (registered trademark), an antenna for NFC, an antenna for millimeter waves, and so forth. Note that a plurality of the mesh wiring layers 20 may be formed on the substrate 11. In this case, the lengths of the plurality of mesh wiring layers 20 may differ from each other, and may correspond to different frequency bands from each other. Alternatively, in a case in which the wiring board 10 does not have radio wave transmission/reception functions, each mesh wiring layer 20 may have functions such as, for example, hovering (a function enabling a user to perform operations even without directly touching the display), fingerprint authentication, heater, noise reduction (shielding), and so forth.

The mesh wiring layer 20 has a basal side portion (transfer portion) 20a on the power supply unit 40 side, and a distal side portion (transmission/reception portion) 20b connected to the basal side portion 20a. The basal side portion 20a and the distal side portion 20b are each substantially rectangular in shape, in plan view. In this case, the length (Y-direction distance) of the distal side portion 20b may be longer than the length (Y-direction distance) of the basal side portion 20a, and the width (X-direction distance) of the distal side portion 20b may be broader than the width (X-direction distance) of the basal side portion 20a.

With the mesh wiring layer 20, the longitudinal direction thereof is parallel to the Y direction, and the lateral direction thereof is parallel to the X direction. The length Lₐ of the mesh wiring layer 20 in the longitudinal direction (Y direction) can be selected from a range of 2 mm or more and 100 mm or less, or may be selected from a range of 3 mm or more and 100 mm or less, for example. A width Wₐ in the lateral direction (X direction) of the mesh wiring layer 20 (distal side portion 20b) can be selected from a range of 1 mm or more and 10 mm or less, for example. In particular, the mesh wiring layer 20 may be a millimeter wave antenna, and in a case in which the mesh wiring layer 20 is a millimeter wave antenna, the length Lₐ of the mesh wiring layer 20 can be selected from a range of 1 mm or more and 10 mm or less, more preferably 1.5 mm or more and 5 mm or less. Note that while FIG. 3 illustrates a form of a case in which the mesh wiring layer 20 functions as a monopole antenna, this is not restrictive, and forms may be used such as a dipole antenna, a loop antenna, a slot antenna, a microstrip antenna, a patch antenna, and so forth.

The mesh wiring layer 20 is formed with respective metal lines being formed in a grid-like or fishnet-like form, having a repetitive pattern in the X direction and in the Y direction. That is to say, the mesh wiring layer 20 has a pattern form that is made up of portions extending in the X direction (second-direction wiring lines 22), and portions extending in the X direction (first-direction wiring lines 21)

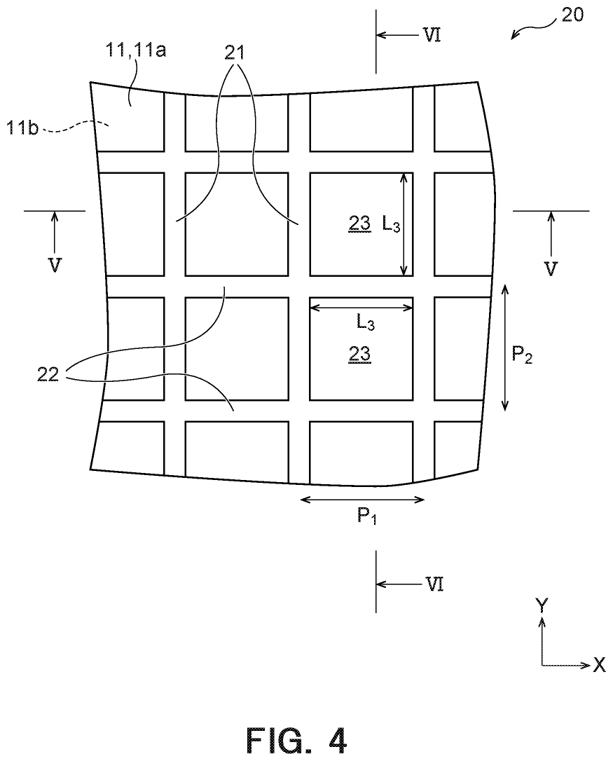

As illustrated in FIG. 4, the mesh wiring layer 20 includes a plurality of the first-direction wiring lines (antenna wiring lines) 21 having functions as an antenna, and a plurality of the second-direction wiring lines (antenna interconnection wiring lines) 22 interconnecting the plurality of first-direction wiring lines 21. Specifically, the plurality of first-direction wiring lines 21 and the plurality of second-direction wiring lines 22 overall and integrally form a grid-like or fishnet-like form. The first-direction wiring lines 21 extend in a direction corresponding to the frequency band of the antenna (longitudinal direction, Y direction), and the second-direction wiring lines 22 extend in a direction orthogonal to the first-direction wiring lines 21 (width direction, X direction). The first-direction wiring lines 21 exhibit functions primarily as an antenna by having the length Lₐ (length of the mesh wiring layer 20 described above, see FIG. 3) corresponding to the predetermined frequency band. On the other hand, the second-direction wiring lines 22 interconnect these first-direction wiring lines 21 to each other, and thereby serve to suppress trouble in which the first-direction wiring lines 21 are disconnected, or the first-direction wiring lines 21 and the power supply unit 40 lose electrical connection, or the like.

In the mesh wiring layer 20, a plurality of openings 23 are formed by being surrounded by the first-direction wiring lines 21 adjacent to each other and the second-direction wiring lines 22 adjacent to each other. Also, the first-direction wiring lines 21 and the second-direction wiring lines 22 are disposed equidistantly to each other. That is to say, the plurality of first-direction wiring lines 21 are disposed equidistantly to each other, and a pitch P₁ thereof may be in a range of 0.01 mm or more and 1 mm or less, for example. Also, the plurality of second-direction wiring lines 22 are disposed equidistantly to each other, and a pitch P₂ thereof may be in a range of 0.01 mm or more and 1 mm or less, for example. In this way, due to the plurality of first-direction wiring lines 21 and the plurality of second-direction wiring lines 22 being each disposed equidistantly, variance in the size of the openings 23 in the mesh wiring layer 20 is eliminated, and the mesh wiring layer 20 can be made to be less visually recognizable by the bare eye. Also, the pitch P₁ of the first-direction wiring lines 21 is equal to the pitch P₂ of the second-direction wiring lines 22. Accordingly, the openings 23 each have a substantially square shape in plan view, and the substrate 11 that has transparency is exposed from each of the openings 23. Thus, the transparency of the wiring board 10 overall can be increased by increasing the area of the openings 23. Note that a length L₃ of one side of the openings 23 may be in a range of 0.01 mm or more and 1 mm or less, for example. Note that while the first-direction wiring lines 21 and the second-direction wiring lines 22 are orthogonal to each other, this is not restrictive, and these may intersect at acute angles or obtuse angles. For example, the first-direction wiring lines 21 and the second-direction wiring lines 22 may intersect obliquely (non-right angle), such that the openings 23 are formed to be rhombic in plan view. The first-direction wiring lines 21 and the second-direction wiring lines 22 do not have to be parallel to either of the X direction and the Y direction. Alternatively, one of the first-direction wiring lines 21 and the second-direction wiring lines 22 may be parallel to the X direction or the Y direction. Also, the shapes of the openings 23 preferably are the same shape and the same size over the entire area, but do not have to be uniform over the entire area, with changes being made thereto depending on the location, or the like.

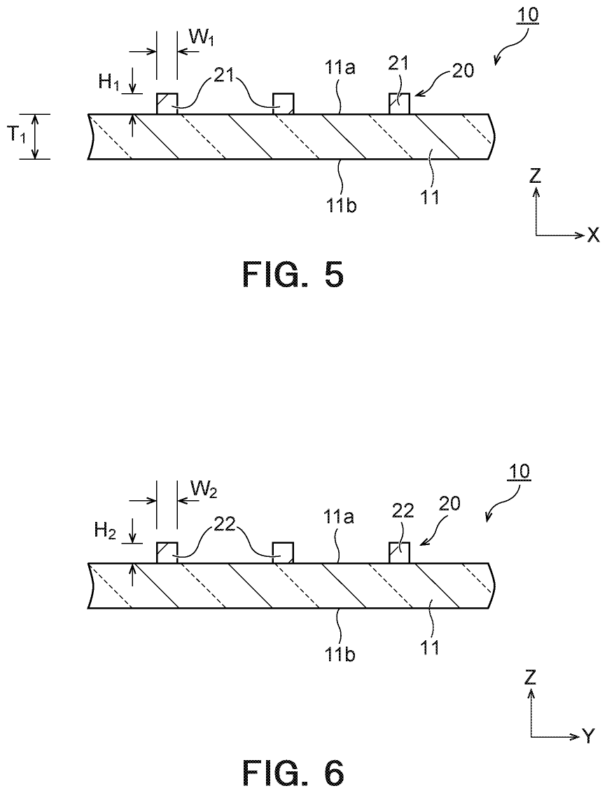

As illustrated in FIG. 5, the cross-section of each first-direction wiring line 21 perpendicular to the longitudinal direction (X-direction cross-section) is a substantially rectangular shape or a substantially square shape. In this case, the sectional shape of the first-direction wiring lines 21 is substantially uniform in the longitudinal direction (Y direction) of the first-direction wiring lines 21. Also, as illustrated in FIG. 6, the cross-sectional shape of each second-direction wiring line 22 perpendicular to the longitudinal direction (Y-direction cross-section) is a substantially rectangular shape or a substantially square shape, and is substantially the same as the sectional shape of the first-direction wiring lines 21 described above (X-direction cross-section). In this case, the sectional shape of the second-direction wiring lines 22 is substantially uniform in the longitudinal direction (X direction) of the second-direction wiring lines 22. The sectional shape of the first-direction wiring lines 21 and the second-direction wiring lines 22 does not necessarily have to be a substantially rectangular shape or a substantially square shape, and for example may be a substantially trapezoidal shape in which the front face side (plus side in the Z direction) is narrower than the rear face side (minus side in the Z direction), or a shape in which side faces situated on both sides in the longitudinal direction are curved.

In the present embodiment, a line width W₁ (length in X direction, see FIG. 5) of the first-direction wiring lines 21 and a line width W₂ (length in Y direction, see FIG. 6) of the second-direction wiring lines 22 are not limited in particular, and can be selected as appropriate in accordance with the usage. For example, the line width W₁ of the first-direction wiring lines 21 can be selected from a range of 0.1 μm or more and 5.0 μm or less, and preferably is 0.2 μm or more and 2.0 μm or less. Also, the line width W₂ of the second-direction wiring lines 22 can be selected from a range of 0.1 μm or more and 5.0 μm or less, and preferably is 0.2 μm or more and 2.0 μm or less. Further, a height H1 (length in Z direction, see FIG. 5) of the first-direction wiring lines 21 and a height H2 (length in Z direction, see FIG. 6) of the second-direction wiring lines 22 are not limited in particular and can be selected as appropriate in accordance with the usage. The height H1 of the first-direction wiring lines 21 and the height H2 of the second-direction wiring lines 22 can each be selected from a range of 0.1 μm or more and 5.0 μm or less for example, and preferably are 0.2 μm or more and 2.0 μm or less.

It is sufficient for the material of the first-direction wiring lines 21 and the second-direction wiring lines 22 to be a metal material that has conductivity. The material of the first-direction wiring lines 21 and the second-direction wiring lines 22 is copper in the present embodiment, but is not limited thereto. Metal materials (including alloys) such as gold, silver, copper, platinum, tin, aluminum, iron, nickel, and so forth, for example, can be used as the material of the first-direction wiring lines 21 and the second-direction wiring lines 22. Also, the first-direction wiring lines 21 and the second-direction wiring lines 22 may be plating layers formed by electrolytic plating.

An overall aperture ratio At of the mesh wiring layer 20 may be in a range of 87% or more and less than 100%. By setting the aperture ratio At of the overall wiring board 10 to this range, conductivity and transparency of the wiring board 10 can be secured. Note that an aperture ratio is a ratio (%) of area of opening regions (regions where no metal portions, such as the first-direction wiring lines 21, second-direction wiring lines 22, and so forth, are present, and the substrate 11 is exposed) within a unit area of a predetermined region (e.g., the entire mesh wiring layer 20).

Also, a protective layer may be formed on the first face 11a of the substrate 11 so as to cover the mesh wiring layer 20, although not illustrated. The protective layer is to protect the mesh wiring layer 20, and is formed so as to cover at least the mesh wiring layer 20 on the substrate 11. Acrylic resins such as polymethyl (meth)acrylate, polyethyl (meth)acrylate, and so forth, and denatured resins and copolymers thereof, polyvinyl resins such as polyester, polyvinyl alcohol, polyvinyl acetate, polyvinyl acetal, polyvinyl butyral, and so forth, and copolymers thereof, polyurethane, epoxy resin, polyamide, chlorinated polyolefin, and so forth, and like insulating resins that are colorless and transparent, can be used as the material of the protective layer.

Referencing FIG. 3 again, the power supply unit 40 is electrically connected to the mesh wiring layer 20. This power supply unit 40 is made up of a thin-plate-like member that is substantially rectangular and that has conductivity. The longitudinal direction of the power supply unit 40 is parallel to the X direction, and the lateral direction of the power supply unit 40 is parallel to the Y direction. Also, the power supply unit 40 is disposed on the longitudinal-direction end portion (minus-side end portion in the Y direction) of the substrate 11. Metal materials (including alloys) such as gold, silver, copper, platinum, tin, aluminum, iron, nickel, and so forth, for example, can be used as the material of the power supply unit 40. When the wiring board 10 is assembled into the image display device 60 (see FIG. 1 and FIG. 2), the power supply unit 40 is electrically connected to the communication module 63 of the image display device 60. Note that while the power supply unit 40 is provided on the first face 11a of the substrate 11, this is not restrictive, and part or all of the power supply unit 40 may be situated on an outer side from the peripheral edge of the substrate 11. Also, the power supply unit 40 may be formed flexibly, such that the power supply unit 40 can run around to a side face and a rear face of the image display device 60 for electrical connection on the side face and the rear face.

### [Manufacturing Method of Wiring Board]

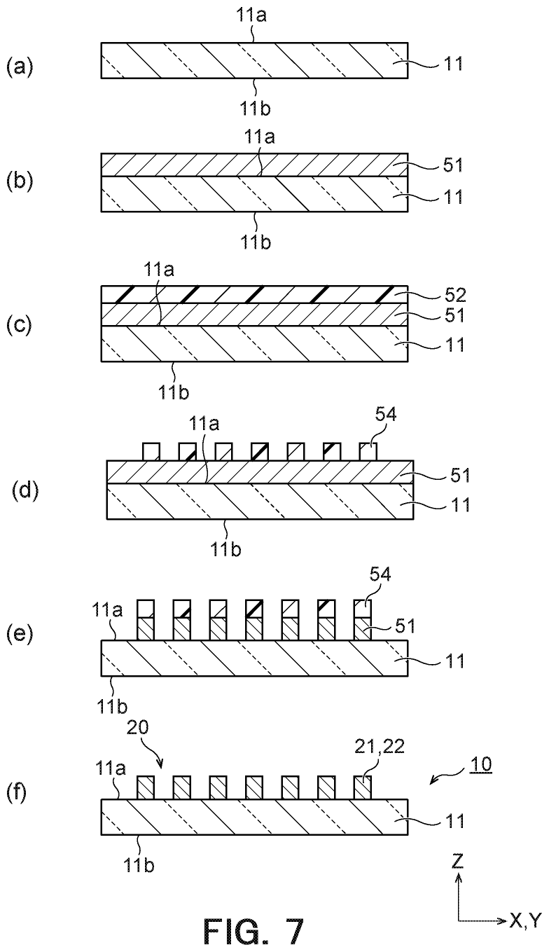

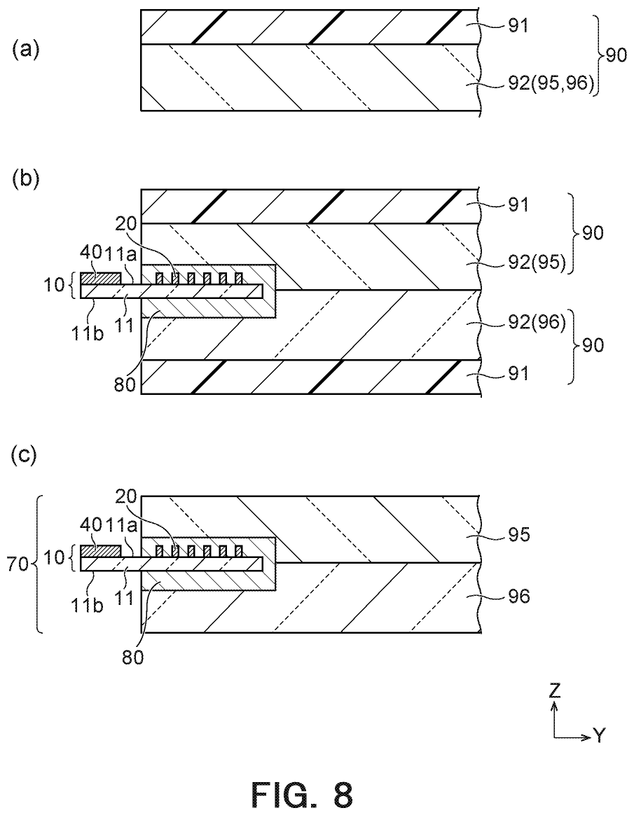

Next, a manufacturing method of the image display device laminate 70 according to the present embodiment will be described with reference to FIGS. 7(a) to 7(f) and FIGS. 8(a) to 8(c). FIGS. 7(a) to 7(f) and FIGS. 8(a) to 8(c) are sectional views illustrating the manufacturing method of the image display device laminate 70 according to the present embodiment.

As illustrated in FIG. 7(a), the substrate 11 that has transparency is prepared.

Next, the mesh wiring layer 20 including the plurality of first-direction wiring lines 21, and the plurality of second-direction wiring lines 22 interconnecting the plurality of first-direction wiring lines 21 is formed on the substrate 11.

At this time, first, as illustrated in FIG. 7(b), metal foil 51 is laminated on substantially the entire region of the first face 11a of the substrate 11. The thickness of the metal foil 51 in the present embodiment may be 0.1 μm or more and 5.0 μm or less. The metal foil 51 in the present embodiment may contain copper.

Next, as illustrated in FIG. 7(c), photo-curing insulating resist 52 is supplied to substantially the entire region of the surface of the metal foil 51. Examples of this photo-curing insulating resist 52 include organic resins such as acrylic resins, epoxy-based resins, and so forth.

Next, as illustrated in FIG. 7(d), an insulating layer 54 is formed by photolithography. In this case, the photo-curing insulating resist 52 is patterned by photolithography, thereby forming the insulating layer 54 (resist pattern). At this time, the insulating layer 54 is formed such that the metal foil 51 corresponding to the first-direction wiring lines 21 and the second-direction wiring lines 22 is exposed.

Next, as illustrated in FIG. 7(e), the metal foil 51 situated at portions on the first face 11a of the substrate 11 not covered by the insulating layer 54 is removed. At this time, the metal foil 51 is etched such that the first face 11a of the substrate 11 is exposed, by performing wet processing using such as ferric chloride, cupric chloride, strong acids such as sulfuric acid, hydrochloric acid, or the like, persulfate, hydrogen peroxide, or aqueous solutions thereof, or combinations of the above, or the like.

Next, as illustrated in FIG. 7(f), the insulating layer 54 is removed. At this time, the insulating layer 54 on the metal foil 51 is removed by performing wet processing using a permanganate solution, N-methyl-2-pyrrolidone, acid or alkali solutions, or the like, or dry processing using oxygen plasma.

Thus, the wiring board 10 that has the substrate 11, and the mesh wiring layer 20 provided on the substrate 11, is obtained. In this case, the mesh wiring layer 20 includes the first-direction wiring lines 21 and the second-direction wiring lines 22. Thereafter, the wiring board 10 is cut to a desired size.

Next, the first transparent adhesive layer 95, the wiring board 10, and the second transparent adhesive layer 96 are laminated on each other. At this time, first, as illustrated in FIG. 8(a), an OCA sheet 90 is prepared that includes, for example, a release film 91 of polyethylene terephthalate (PET), and an OCA layer 92 (first transparent adhesive layer 95 or second transparent adhesive layer 96) laminated on the release film 91. At this time, the OCA layer 92 may be a layer obtained by coating a curable adhesive layer composition that is in a liquid state and that includes a polymerizable compound, on the releasing film 91, and cured by using ultraviolet rays (UV) or the like, for example. This curable adhesive layer composition contains a polar-group-containing monomer.

Next, as illustrated in FIG. 8(b), the OCA layers 92 of the OCA sheets 90 are applied to the wiring board 10.

Thereafter, as illustrated in FIG. 8(c), the release films 91 are removed by separation from the OCA layers 92 of the OCA sheets 90 applied to the wiring board 10, thereby obtaining the first transparent adhesive layer 95 (OCA layer 92), the wiring board 10, and the second transparent adhesive layer 96 (OCA layer 92), which are laminated on each other.

Now, as described above, the curable adhesive layer composition from which the OCA layers 92 are made contains the polar-group-containing monomer. Accordingly, when applying the OCA layers 92 of the OCA sheets 90 to the wiring board 10, part of the OCA layers 92 and part of the substrate 11 of the wiring board 10 fuse, thereby forming the intermediate layer 80 covering the wiring board 10.

Thus, the image display device laminate 70 including the first transparent adhesive layer 95, the second transparent adhesive layer 96, the wiring board 10, and the intermediate layer 80 is obtained. Thereafter, the display device 61 is laminated on the image display device laminate 70, thereby obtaining the image display device 60 including the image display device laminate 70 and the display device 61 laminated on the image display device laminate 70.

### Effects of Present Embodiment

Next, the effects of the present embodiment having such a configuration will be described.

As illustrated in FIG. 1 and FIG. 2, the wiring board 10 is assembled into the image display device 60 that has the display device 61. At this time, the wiring board 10 is disposed above the display device 61. The mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

According to the present embodiment, a partial region of the substrate 11 is disposed in a partial region between the first transparent adhesive layer 95 and the second transparent adhesive layer 96. Also, the intermediate layer 80 is situated between the wiring board 10 and the first transparent adhesive layer 95, and is also situated between the wiring board 10 and the second transparent adhesive layer 96. Accordingly, reflection of visible light at the interface between the substrate 11 and the first transparent adhesive layer 95, and the interface between the substrate 11 and the second transparent adhesive layer 96, can be suppressed. Accordingly, when the observer observes the image display device 60 from the light-emitting face 64 side, the substrate 11 of the wiring board 10 can be made to be less visually recognizable by the bare eye. In particular, in a case in which the first transparent adhesive layer 95 and the second transparent adhesive layer 96 each have an area that is greater than that of the substrate 11, the outer edge of the substrate 11 can be made to be less visually recognizable by the bare eye of the observer, and the observer can be kept from recognizing the presence of the substrate 11.

Also, according to the present embodiment, the wiring board 10 includes the substrate 11, and the mesh wiring layer 20 disposed on the substrate 11. Also, the substrate 11 has transparency. Further, the mesh wiring layer 20 has a conductor portion serving as a formation portion of a non-transparent conductor layer, and a mesh-like pattern with a great number of openings. Accordingly, the transparency of the wiring board 10 is secured. Thus, when the wiring board 10 is disposed over the display device 61, the display device 61 can be visually recognized from the openings 23 of the mesh wiring layer 20, and visual recognition of the display device 61 is not impeded.

### MODIFICATIONS

Next, modifications of the image display device laminate 70 will be described.

### First Modification

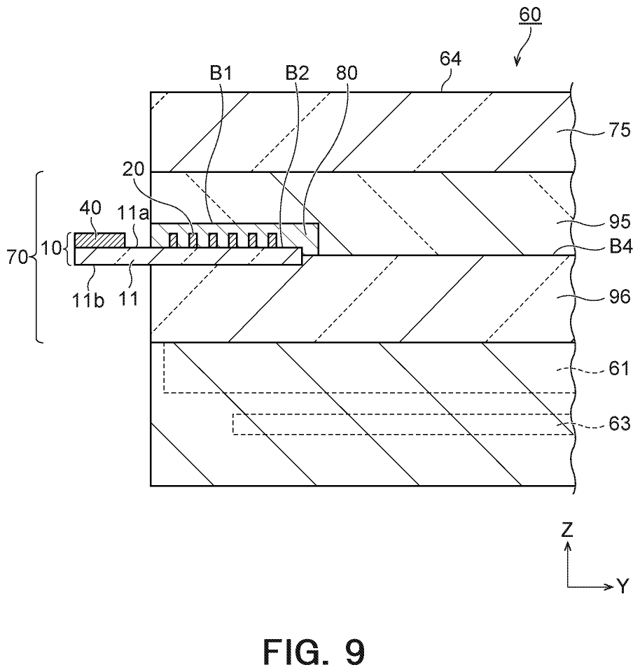

FIG. 9 illustrates a first modification of the image display device laminate. The modification illustrated in FIG. 9 differs with respect to the point that the intermediate layer 80 is not situated between the wiring board 10 and the second transparent adhesive layer 96, and other configurations are substantially the same as those of the embodiment illustrated in FIG. 1 to FIG. 8 described above. In FIG. 9, portions that are the same as in the embodiment illustrated in FIG. 1 to FIG. 8 are denoted by the same symbols, and detailed description will be omitted.

In the first modification illustrated in FIG. 9, the intermediate layer 80 is not situated between the wiring board 10 and the second transparent adhesive layer 96. In the present embodiment, the intermediate layer 80 is situated only between the wiring board 10 and the first transparent adhesive layer 95. In this case, for example, the intermediate layer 80 can be kept from being provided between the wiring board 10 and the second transparent adhesive layer 96 by using a curable adhesive layer composition not containing the polar-group-containing monomer for the OCA layer 92 making up the second transparent adhesive layer 96.

In the present embodiment as well, reflection of visible light at the interface between the substrate 11 and the first transparent adhesive layer 95 can be suppressed. Accordingly, the substrate 11 of the wiring board 10 can be made to be less visually recognizable by the bare eye when an observer observes the image display device 60 from the light-emitting face 64 side.

### Second Modification

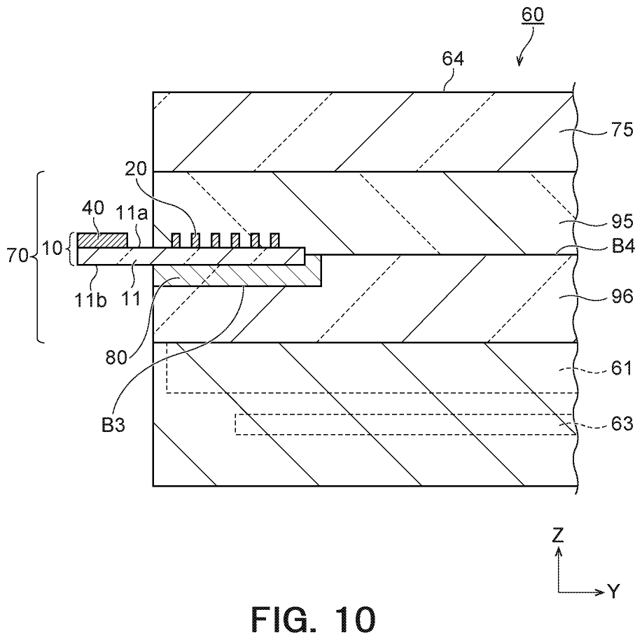

FIG. 10 illustrates a first modification of the image display device laminate. The modification illustrated in FIG. 10 differs with respect to the point that the intermediate layer 80 is not situated between the wiring board 10 and the first transparent adhesive layer 95, and other configurations are the same as those of the embodiment illustrated in FIG. 1 to FIG. 9 described above. In FIG. 10, portions that are the same as in the embodiment illustrated in FIG. 1 to FIG. 9 are denoted by the same symbols, and detailed description will be omitted.

In the second modification illustrated in FIG. 10, the intermediate layer 80 is not situated between the wiring board 10 and the first transparent adhesive layer 95. In the present modification, the intermediate layer 80 is situated only between the wiring board 10 and the second transparent adhesive layer 96. In this case, for example, the intermediate layer 80 can be kept from being provided between the wiring board 10 and the first transparent adhesive layer 95 by using a curable adhesive layer composition not containing the polar-group-containing monomer for the OCA layer 92 making up the first transparent adhesive layer 95.

In the present modification as well, reflection of visible light at the interface between the substrate 11 and the second transparent adhesive layer 96 can be suppressed. Accordingly, the substrate 11 of the wiring board 10 can be made to be less visually recognizable by the bare eye.

### Third Modification

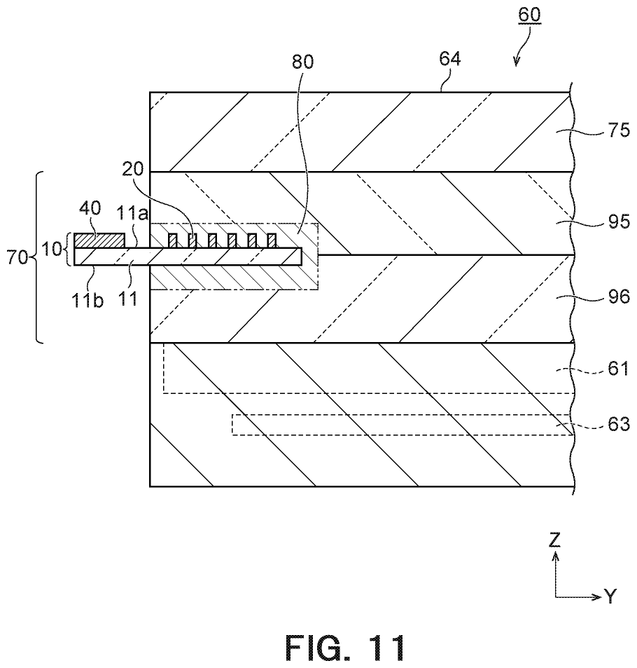

FIG. 11 illustrates a modification of the image display device laminate. The modification illustrated in FIG. 11 differs with respect to the point that the interface B1 between the intermediate layer 80 and the first transparent adhesive layer 95, and so forth, are not present, and other configurations are the same as those of the embodiment illustrated in FIG. 1 to FIG. 10 described above. In FIG. 11, portions that are the same as in the embodiment illustrated in FIG. 1 to FIG. 10 are denoted by the same symbols, and detailed description will be omitted.

In the modification illustrated in FIG. 11, the interface B1 between the intermediate layer 80 and the first transparent adhesive layer 95, the interface B2 between the intermediate layer 80 and the substrate 11, and the interface B3 between the intermediate layer 80 and the second transparent adhesive layer 96 each are not present. Accordingly, reflection of visible light is suppressed among the first transparent adhesive layer 95, the substrate 11, the second transparent adhesive layer 96, and the intermediate layer 80, and the substrate 11 can be made to be less visually recognizable by the bare eye of the observer. Note that “interface is not present” in the present specification means that the interface cannot be visually recognized when observed using an electron microscope (e.g., a transmission electron microscope (TEM)).

As described above, the intermediate layer 80 is formed by part of the OCA layers 92 and part of the substrate 11 of the wiring board 10 fusing. Accordingly, mixing a part of the OCA layers 92 and a part of the substrate 11 of the wiring board 10 in a gradient manner yields the intermediate layer 80 in which the above-described interface B1 to interface B3 are not present.

In the present modification, the refractive index of the intermediate layer 80 changes so that the difference between the refractive index of the intermediate layer 80 and the refractive index of the first transparent adhesive layer 95 gradually changes to be smaller, the closer to the first transparent adhesive layer 95. Also, the refractive index of the intermediate layer 80 changes so that the difference between the refractive index of the intermediate layer 80 and the refractive index of the substrate 11 gradually changes to be smaller, the closer to the substrate 11. Further, the refractive index of the intermediate layer 80 changes so that the difference between the refractive index of the intermediate layer 80 and the refractive index of the second transparent adhesive layer 96 gradually changes to be smaller, the closer to the second transparent adhesive layer 96. Accordingly, reflection of visible light between the first transparent adhesive layer 95 and the intermediate layer 80, between the substrate 11 and the intermediate layer 80, and between the second transparent adhesive layer 96 and the intermediate layer 80 is suppressed, so that the substrate 11 is less visually recognizable by the bare eye of the observer.

In this way, due to each of the interface B1 to the interface B3 not being present, reflection of visible light between the first transparent adhesive layer 95 and the intermediate layer 80, between the substrate 11 and the intermediate layer 80, and between the second transparent adhesive layer 96 and the intermediate layer 80 is suppressed, and the substrate 11 less visually recognizable by the bare eye of the observer.

Next, modifications of the wiring board will be described.

### First Modification

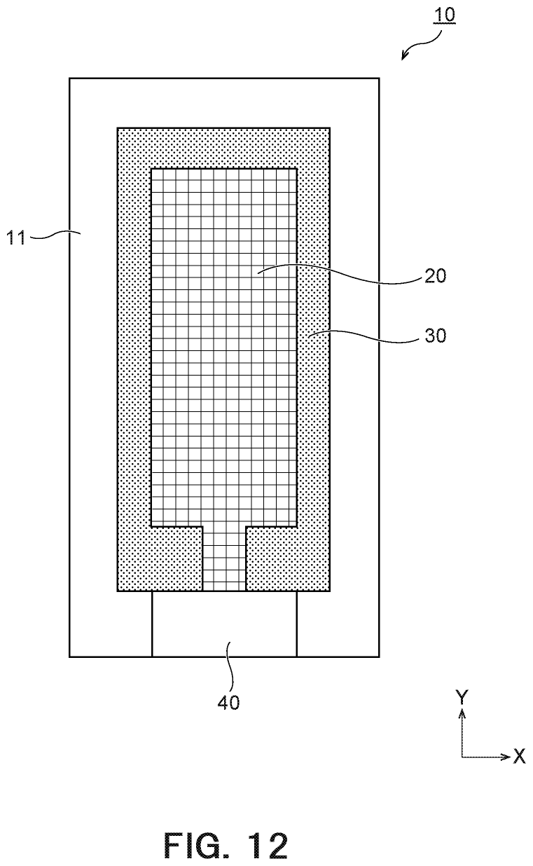

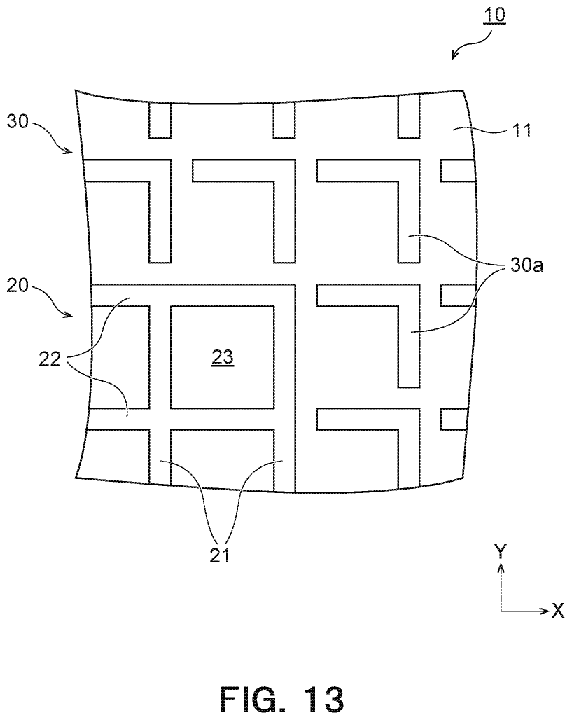

FIG. 12 and FIG. 13 illustrate a first modification of the wiring board. The modification illustrated in FIG. 12 and FIG. 13 differs with respect to the point of a dummy wiring layer 30 being provided around the mesh wiring layer 20, and other configurations are generally the same as the form described above, which is illustrated in FIG. 1 to FIG. 11. In FIG. 12 and FIG. 13, portions that are the same as in the form illustrated in FIG. 1 to FIG. 11 are denoted by the same signs, and detailed description will be omitted. In the wiring board 10 illustrated in FIG. 12, the dummy wiring layer 30 is provided so as to follow around the mesh wiring layer 20. Unlike the mesh wiring layer 20, this dummy wiring layer 30 does not substantially function as an antenna.

As illustrated in FIG. 12, the dummy wiring layer 30 is made up of a repetition of the dummy wiring lines 30a having a predetermined unit pattern shape. That is to say, the dummy wiring layer 30 includes a plurality of the dummy wiring lines 30a of the same shape, and each dummy wiring line 30a is electrically isolated from each of the mesh wiring layers 20 (first-direction wiring lines 21 and second-direction wiring lines 22). Also, the plurality of dummy wiring lines 30a are regularly disposed over the entire region within the dummy wiring layer 30. The plurality of dummy wiring lines 30a are distanced from each other in a planar direction, and are also disposed so as to protrude on the substrate 11. That is to say, each dummy wiring line 30a is electrically isolated from the mesh wiring layer 20, the power supply unit 40, and other dummy wiring lines 30a. The dummy wiring lines 30a are each generally L-shaped in plan view.

In this case, the dummy wiring lines 30a have a shape in which part of the unit pattern shape of the mesh wiring layer 20 described above (see FIG. 4) is missing. Thus, difference between the mesh wiring layer 20 and the dummy wiring layer 30 can be made to be less visually recognizable, and the mesh wiring layer 20 disposed on the substrate 11 can be made to be difficult to see. An aperture ratio of the dummy wiring layer 30 may be the same as the aperture ratio of the mesh wiring layer 20, or may be different, but preferably is near the aperture ratio of the mesh wiring layer 20.

Thus, by disposing the dummy wiring layer 30 that is electrically isolated from the mesh wiring layer 20 around the mesh wiring layer 20, an outer edge of the mesh wiring layer 20 can be made obscure. Accordingly, the mesh wiring layer 20 can be made to be difficult to see on the front face of the image display device 60, and the mesh wiring layer 20 can be made to be less visually recognizable by the bare eye of the user of the image display device 60.

### Second Modification

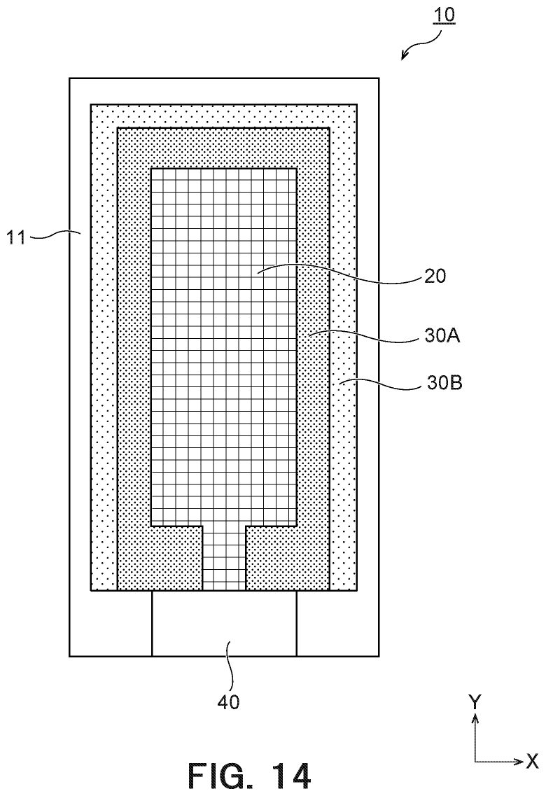

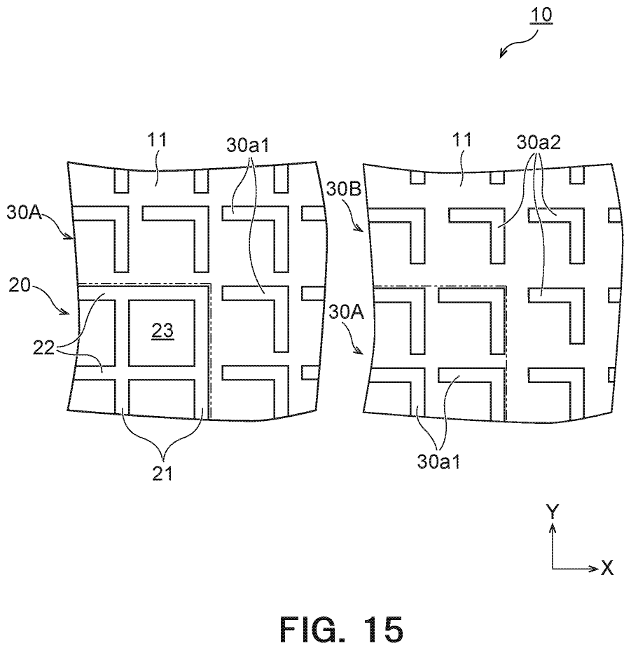

FIG. 14 and FIG. 15 illustrate a second modification of the wiring board. The modification illustrated in FIG. 14 and FIG. 15 differs with respect to the point that a plurality of dummy wiring layers 30A and 30B that have different aperture ratios from each other are provided around the mesh wiring layer 20, and other configurations are generally the same as the forms illustrated in FIG. 1 to FIG. 13 described above. In FIG. 14 and FIG. 15, portions that are the same as in the forms illustrated in FIG. 1 to FIG. 13 are denoted by the same signs, and detailed description will be omitted.

In the wiring board 10 illustrated in FIG. 14, the plurality of (two in this case) of dummy wiring layers 30A and 30B (first dummy wiring layer 30A and second dummy wiring layer 30B) that have different aperture ratios from each other are provided so as to follow around the mesh wiring layer 20. Specifically, the first dummy wiring layer 30A is disposed so as to follow around the mesh wiring layer 20, and the second dummy wiring layer 30B is disposed so as to follow around the first dummy wiring layer 30A. Unlike the mesh wiring layer 20, these dummy wiring layers 30A and 30B do not substantially function as an antenna.

As illustrated in FIG. 15, the first dummy wiring layer 30A is made up of a repetition of dummy wiring lines 30a1 that have a predetermined unit pattern form. Also, the second dummy wiring layer 30B is made up of a repetition of dummy wiring lines 30a2 that have a predetermined unit pattern form. That is to say, the dummy wiring layers 30A and 30B include a plurality of the dummy wiring lines 30a1 and 30a2 of the same shapes, respectively, and each of the dummy wiring lines 30a1 and 30a2 is electrically isolated from the mesh wiring layer 20. Also, each of the dummy wiring lines 30a1 and 30a2 is regularly disposed within the entire region of the respective dummy wiring layers 30A and 30B. The dummy wiring lines 30a1 and 30a2 are each distanced from each other in the planar direction, and are also disposed so as to protrude on the substrate 11. The dummy wiring lines 30a1 and 30a2 are each electrically isolated from the mesh wiring layer 20, the power supply unit 40, and other dummy wiring lines 30a1 and 30a2. Also, the dummy wiring lines 30a1 and 30a2 are each generally L-shaped in plan view.

In this case, the dummy wiring lines 30a1 and 30a2 have shapes in which part of the unit pattern shape of the mesh wiring layer 20 described above (see FIG. 4) is missing. Thus, difference between the mesh wiring layer 20 and the first dummy wiring layer 30A, and difference between the first dummy wiring layer 30A and the second dummy wiring layer 30B can be made to be less visually recognizable, and the mesh wiring layer 20 disposed on the substrate 11 can be made to be difficult to see. The aperture ratio of the first dummy wiring layer 30A is larger than the aperture ratio of the mesh wiring layer 20, and the aperture ratio of the first dummy wiring layer 30A is larger than the aperture ratio of the second dummy wiring layer 30B.

Note that the area of each dummy wiring line 30a1 of the first dummy wiring layer 30A is greater than the area of each dummy wiring line 30a2 of the second dummy wiring layer 30B. In this case, the line width of each dummy wiring line 30a1 is the same as the line width of each dummy wiring line 30a2, but this is not restrictive, and the line width of each dummy wiring line 30a1 may be wider than the line width of each dummy wiring line 30a2. Also, three or more dummy wiring layers with aperture ratios different from each other may be provided. In this case, the aperture ratio of each dummy wiring layer preferably gradually increases from those close to the mesh wiring layer 20 toward those far away.

Thus, by disposing the dummy wiring layers 30A and 30B that are electrically isolated from the mesh wiring layer 20, the outer edge of the mesh wiring layer 20 can be made obscure. Accordingly, the mesh wiring layer 20 can be made difficult to see on the front face of the image display device 60, and the mesh wiring layer 20 can be made to be less visually recognizable by the bare eye of the user of the image display device 60.

### Third Modification

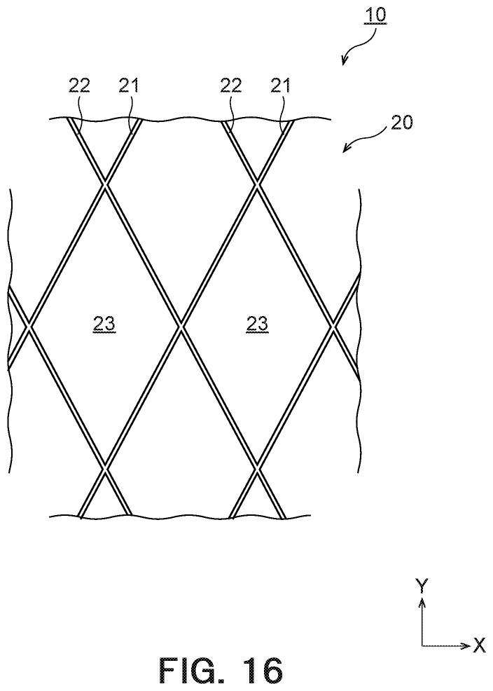

FIG. 16 illustrates a third modification of the wiring board. The modification illustrated in FIG. 16 differs in the planar form of the mesh wiring layer 20, and other configurations are generally the same as the forms illustrated in FIG. 1 to FIG. 15 described above. In FIG. 16, portions that are the same as in the forms illustrated in FIG. 1 to FIG. 15 are denoted by the same signs, and detailed description will be omitted.

FIG. 16 is an enlarged plan view illustrating the mesh wiring layer 20 according to a modification. In FIG. 16, the first-direction wiring lines 21 and the second-direction wiring lines 22 intersect obliquely (non-orthogonally), and each opening 23 is formed as a rhombus shape in plan view. The first-direction wiring lines 21 and the second-direction wiring lines 22 are each not parallel to either of the X direction and the Y direction, but one of the first-direction wiring lines 21 and the second-direction wiring lines 22 may be parallel to the X direction or the Y direction.

### EXAMPLES

Next, specific examples according to the present embodiment will be described.

### Example A1

An image display device laminate having the configuration illustrated in FIG. 2 was fabricated. In this case, a substrate made of polyethylene terephthalate, 50 μm thick, was used as the substrate of the wiring board. Also, an OCA layer made of acrylic resin, 50 μm thick, was used as the first transparent adhesive layer and the second transparent adhesive layer. An acrylic resin containing 0.1% by weight or more of an ethylhexyl acrylate monomer was used as the OCA layer here.

Also, the refractive index of the intermediate layer was 1.555. Also, the refractive index of the first transparent adhesive layer was 1.55. Also, the refractive index of the substrate was 1.57. Further, the refractive index of the second transparent adhesive layer was 1.55. At this time, the refractive index was measured on the basis of Method A of JIS K-7142, using a refractometer (so-called Abbe refractometer) (NAR-1T SOLID, manufactured by ATAGO Co., Ltd.).

Next, non-visibility testing was performed. In the non-visibility testing, those regarding which the outer edge of the wiring board could not be visually discerned whatsoever when observing the front face of the substrate under a general visual inspection environment from angles of 30°, 60°, and 90°, were determined to be “A (excellent)”. Also, those regarding which the outer edge of the wiring board could not be visually discerned when observing the front face of the substrate under a general visual inspection environment from angles of 30°, 60°, and 90°, were determined to be “B (good)”. Also, those regarding which the outer edge of the wiring board could be visually discerned when observing the front face of the substrate under a general visual inspection environment from angles of 30°, 60°, and 90°, were determined to be “C (poor)”.

### Example A2

An image display device laminate was fabricated in the same way as Example A1, other than fabricating an image display device laminate having the configuration illustrated in FIG. 9, and non-visibility testing was performed.

### Example A3

An image display device laminate was fabricated in the same way as Example A1, other than fabricating an image display device laminate having the configuration illustrated in FIG. 10, and non-visibility testing was performed.

### Example A4

An image display device laminate was fabricated in the same way as Example A1, other than fabricating an image display device laminate having the configuration illustrated in FIG. 11, and that after laminating the substrate, the first transparent adhesive layer, and the second transparent adhesive layer, the image display device laminate was placed in a 60° C. oven and left standing for 72 hours, and non-visibility testing was performed.

### Reference Example A1

An image display device laminate was fabricated in the same way as Example A1, other than that the refractive index of the intermediate layer was 1.64, and that an OCA layer made of acrylic resin having a refractive index of 1.65 was used as the first transparent adhesive layer and the second transparent adhesive layer, and non-visibility testing was performed.

The results of the above are shown in Table 1 and Table 2.

TABLE 1

| | | | | Refractive |
|---|---|---|---|---|
| | Refractive | Refractive | | index |
| | index of | index of first | Refractive | of second |
| | intermediate | transparent | index | transparent |
| | layer | adhesive layer | of substrate | adhesive layer |
| Example A1 | 1.555 | 1.55 | 1.57 | 1.55 |
| Example A2 | 1.555 | 1.55 | 1.57 | 1.55 |
| Example A3 | 1.555 | 1.55 | 1.57 | 1.55 |
| Example A4 | 1.555 | 1.55 | 1.57 | 1.55 |
| Reference | 1.64 | 1.65 | 1.57 | 1.65 |
| Example A1 | | | | |

TABLE 2

| | | | Difference between | |
|---|---|---|---|---|
| | Difference between | Difference | refractive index of | |
| | refractive index of | between | intermediate layer | |
| | intermediate layer | refractive index of | and refractive | |
| | and refractive index | intermediate layer | index of second | |
| | of first adhesive | and refractive | adhesive | Non- |
| | layer | index of substrate | layer | visibility |
| Example A1 | 0.005 | 0.015 | 0.005 | A |
| Example A2 | 0.005 | 0.015 | 0.005 | A |
| Example A3 | 0.005 | 0.015 | 0.005 | A |
| Example A4 | 0.005 | 0.015 | 0.005 | A |
| Reference | 0.01 | 0.07 | 0.01 | B |
| Example A1 | | | | |

As a result, as shown in Table 1, with the image display device laminates according to Example A1 to Example A4, the outer edge of the wiring board could not be visually discerned whatsoever when observing the front face of the substrate under a general visual inspection environment from angles of 30°, 60°, and 90°. Also, with the image display device laminate according to Reference Example A1, the outer edge of the wiring board could not be visually discerned when observing the front face of the substrate under a general visual inspection environment from angles of 30°, 60°, and 90°. Accordingly, it was found that with the image display device laminate according to the present embodiment, the wiring board could be made to be less visually recognizable by the bare eye.

### Second Embodiment

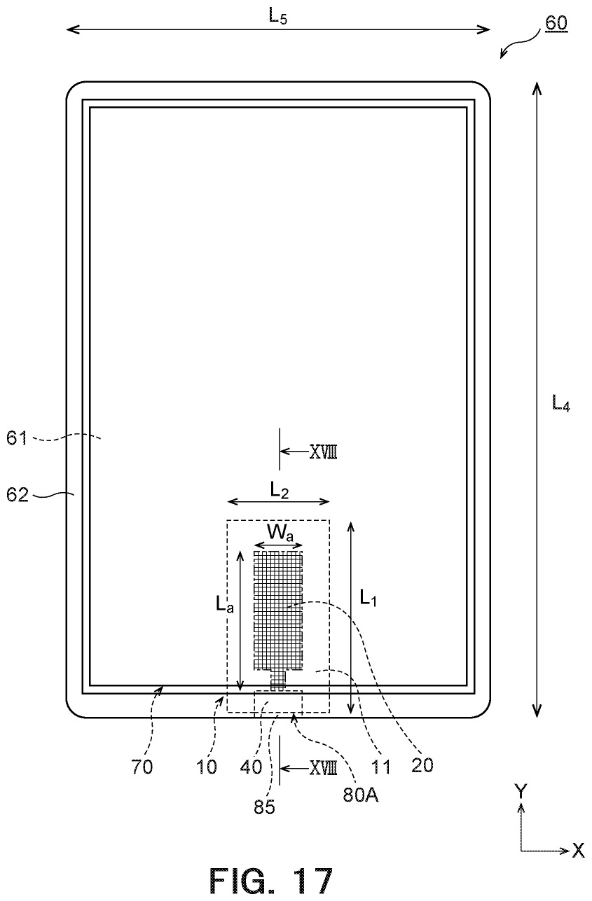

Next, a second embodiment will be described with reference to FIG. 17 to FIG. 19. FIG. 17 to FIG. 19 are diagrams illustrating the second embodiment. In FIG. 17 to FIG. 19, portions that are the same as those of the first embodiment illustrated in FIG. 1 to FIG. 16 may be denoted by the same symbols, and detailed description omitted.

### [Configuration of Image Display Device]

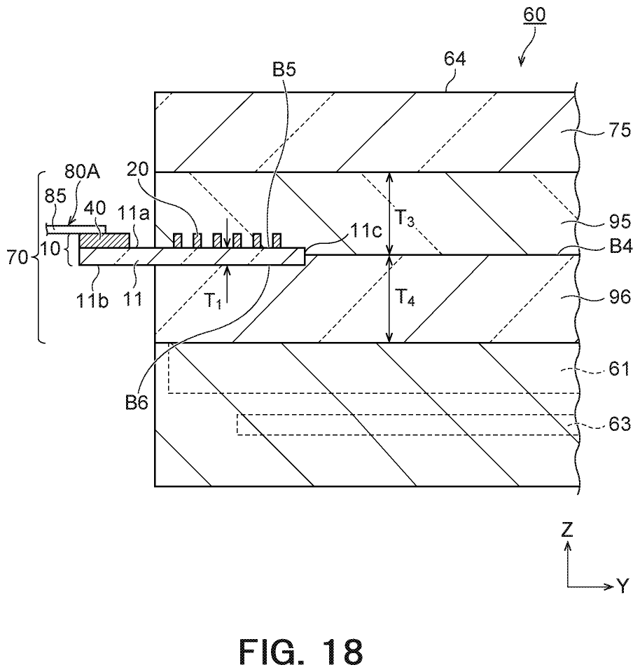

First, the configuration of the image display device according to the present embodiment will be described with reference to FIG. 17 and FIG. 18.

As illustrated in FIG. 17 and FIG. 18, the image display device 60 according to the present embodiment includes the image display device laminate 70, and the display device (display) 61 that is laminated on the image display device laminate 70. Of these, the image display device laminate 70 includes the first transparent adhesive layer (first adhesive layer) 95, the second transparent adhesive layer (second adhesive layer) 96, and the wiring board 10. Of these, the wiring board 10 has the substrate 11 and the mesh wiring layer 20. The substrate 11 includes the first face 11a, the second face 11b that is situated on the opposite side from the first face 11a, and a third face 11c that is situated between the first face 11a and the second face 11b. The mesh wiring layer 20 is disposed on the first face 11a of the substrate 11. Also, the power supply unit 40 is electrically connected to the mesh wiring layer 20. Also, the communication module 63 is disposed on the minus side of the display device 61 in the Z direction. The image display device laminate 70, the display device 61, and the communication module 63 are accommodated in the housing 62. Further, in the present embodiment, the wiring board 10 and a power supply line 85 electrically connected to the wiring board 10 make up a module 80A. In other words, the module 80A includes the above-described wiring board 10, and the power supply line 85 that is electrically connected to the power supply unit 40. When the module 80A is assembled into the image display device 60 that has the display device 61, the power supply unit 40 of the wiring board 10 is electrically connected to the communication module 63 of the image display device 60 via the power supply line 85.

In the present embodiment, in the image display device laminate 70, the difference between the refractive index of the substrate 11 and the refractive index of the first transparent adhesive layer 95 is 0.1 or less, and preferably is 0.05 or less. Also, the difference between the refractive index of the second transparent adhesive layer 96 and the refractive index of the substrate 11 is 0.1 or less, and preferably is 0.05 or less. Further, the difference between the refractive index of the first transparent adhesive layer 95 and the refractive index of the second transparent adhesive layer 96 is preferably 0.1 or less, and more preferably is 0.05 or less. For example, in a case in which the material of the first transparent adhesive layer 95 and the material of the second transparent adhesive layer 96 are acrylic-based resin (refractive index 1.49), the refractive index of the substrate 11 is 1.39 or more and 1.59 or less. Examples of such materials include fluororesins, silicone-based resins, polyolefin resins, polyester-based resins, acrylic-based resins, polycarbonate-based resins, polyimide-based resins, cellulose-based resins, and so forth.

Thus, by suppressing the difference between the refractive index of the substrate 11 and the refractive index of the first transparent adhesive layer 95 to 0.1 or less, reflection of visible light at an interface B5 between the substrate 11 and the first transparent adhesive layer 95 can be suppressed, and the substrate 11 can be made to be less visually recognizable by the bare eye of the observer. Also, by suppressing the difference between the refractive index of the second transparent adhesive layer 96 and the refractive index of the substrate 11 to 0.1 or less, reflection of visible light at an interface B6 between the second transparent adhesive layer 96 and the substrate 11 can be suppressed, and the substrate 11 can be made to be less visually recognizable by the bare eye of the observer. Further, by suppressing the difference between the refractive index of the first transparent adhesive layer 95 and the refractive index of the second transparent adhesive layer 96 to 0.1 or less, reflection of visible light at the interface B4 between the first transparent adhesive layer 95 and the second transparent adhesive layer 96 can be suppressed, and the first transparent adhesive layer 95 and the second transparent adhesive layer 96 can be made to be less visually recognizable by the bare eye of the observer.

Now, as described above, the substrate 11 includes the first face 11a, the second face 11b that is situated on the opposite side from the first face 11a, and the third face 11c situated between the first face 11a and the second face 11b. In this case, the third face 11c of the substrate 11 is covered by the first adhesive layer 95 and the second adhesive layer 96, as illustrated in FIG. 18.

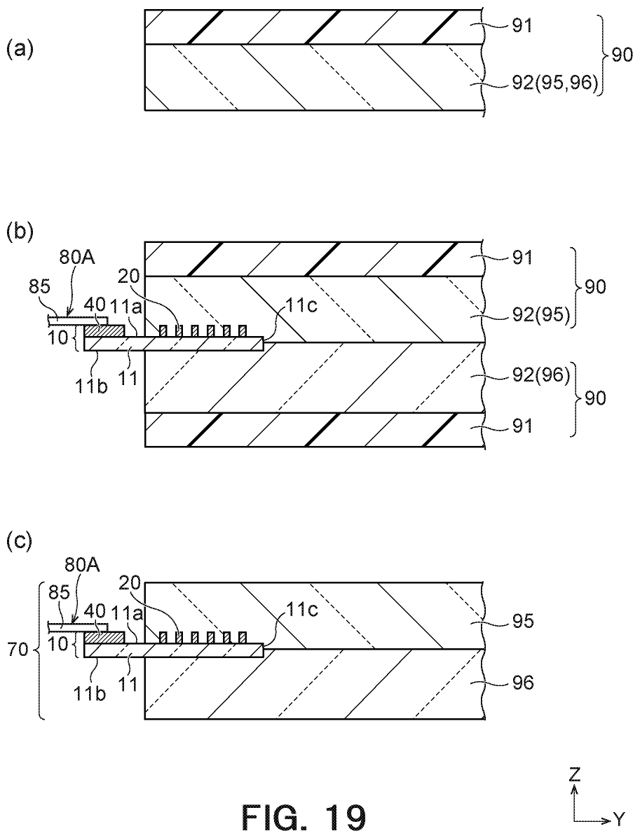

In the present embodiment, surface roughness Ra of the third face 11c is 0.005 μm or more and 0.5 μm or less. Note that the surface roughness Ra is the arithmetic mean roughness, and is measured on the basis of JIS B 0601-2013. Due to the surface roughness Ra of the third face 11c being 0.005 μm or more, adhesion between the OCA layers 92 and the third face 11c can be improved. Also, due to the surface roughness Ra of the third face 11c being 0.5 μm or less, air can be suppressed from entering between the first transparent adhesive layer 95 or the second transparent adhesive layer 96 and the third face 11c. That is to say, at the time of holding the wiring board 10 between the OCA layers 92 (see FIG. 19(b)), air that enters between the OCA layers 92 and the third face 11c can be shunted to the outside more easily, which will be described later. Note that the surface roughness Ra of the third face 11c can be measured using a laser microscope (VK-X250, manufactured by Keyence Corporation), for example.

As described above, the image display device laminate 70 is made up of the wiring board 10, the first transparent adhesive layer 95 that has a greater area than the substrate 11 of the wiring board 10, and the second transparent adhesive layer 96 that has a greater area than the substrate 11. Such an image display device laminate 70 is also provided in the present embodiment.

### [Manufacturing Method of Image Display Device Laminate]

Next, a manufacturing method of the image display device laminate 70 according to the present embodiment will be described.

First, the wiring board 10 is fabricated by the method illustrated in FIGS. 7(a) to 7(f), for example. Thereafter, the wiring board 10 is cut into a desired size. At this time, the wiring board 10 may be cut into the desired size by a blade heated to 100° C. or higher and 300° C. or lower, laser, etching, or the like, for example. Thus, the surface roughness Ra of a cut face (i.e., third face 11c) can be suppressed from increasing as compared to a case of cutting the wiring board 10 using an unheated blade, for example.

Next, the first transparent adhesive layer 95, the wiring board 10, and the second transparent adhesive layer 96 are laminated on each other. At this time, first, as illustrated in FIG. 19(a), the OCA sheet 90 is prepared that includes, for example, the release film 91 of polyethylene terephthalate (PET), and the OCA layer 92 (first transparent adhesive layer 95 or second transparent adhesive layer 96) laminated on the release film 91. At this time, the OCA layer 92 may be a layer obtained by coating a curable adhesive layer composition that is in a liquid state and that includes a polymerizable compound, on the releasing film 91, and then cured by using ultraviolet rays (UV) or the like, for example. This curable adhesive layer composition contains a polar-group-containing monomer.

Next, the OCA layer 92 of the OCA sheet 90 is applied to the wiring board 10, as illustrated in FIG. 19(b). At this time, the power supply line 85 is first electrically applied to the power supply unit 40. At this time, for example, the power supply line 85 is pressure-bonded to the wiring board 10 across an anisotropic conductive film that is not illustrated. At this time, the power supply line 85 is pressure-bonded to the wiring board 10 by applying pressure and heat to the power supply line 85. Thus, the power supply line 85 is electrically connected to the power supply unit 40. In this way, the module 80A including the wiring board 10, and the power supply line 85 electrically connected to the power supply unit 40, is obtained.

Next, the OCA layers 92 of the OCA sheets 90 are applied to the wiring board 10. Thus, the wiring board 10 is held by the OCA layers 92.

Thereafter, as illustrated in FIG. 19(c), the release films 91 are removed by separation from the OCA layers 92 of the OCA sheets 90 applied to the wiring board 10, thereby obtaining the first transparent adhesive layer 95 (OCA layer 92), the wiring board 10, and the second transparent adhesive layer 96 (OCA layer 92), which are laminated on each other.

Thus, the image display device laminate 70 including the first transparent adhesive layer 95, the second transparent adhesive layer 96, and the wiring board 10 is obtained.

Thereafter, the display device 61 is laminated on the image display device laminate 70, thereby obtaining the image display device 60 including the image display device laminate 70 and the display device 61 laminated on the image display device laminate 70.

### Effects of Present Embodiment

Next, the effects of the present embodiment having such a configuration will be described.

As illustrated in FIG. 17 and FIG. 18, the wiring board 10 is assembled into the image display device 60 that has the display device 61. At this time, the wiring board 10 is disposed above the display device 61. The mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

According to the present embodiment, a partial region of the substrate 11 is disposed in a partial region between the first transparent adhesive layer 95 and the second transparent adhesive layer 96. Also, the third face 11c of the substrate 11 is covered by the first adhesive layer 95 and the second adhesive layer 96. Further, the surface roughness Ra of the third face 11c is 0.005 μm or more and 0.5 μm or less. Due to the surface roughness Ra of the third face 11c thus being 0.005 μm or more, adhesion between the OCA layers 92 and the third face 11c can be improved. Also, due to the surface roughness Ra of the third face 11c being 0.5 μm or less, air can be suppressed from entering between the first transparent adhesive layer 95 or the second transparent adhesive layer 96 and the third face 11c.

Now, as described above, after the mesh wiring layer 20 is provided on the substrate 11, the wiring board 10 is cut into a desired size. At this time, there is concern that the surface roughness Ra of the cut face (i.e., third face) of the substrate 11 will become great. In a case in which the surface roughness Ra of the cut face becomes great, there are cases in which air enters in between this cut face, and the first transparent adhesive layer 95 or the second transparent adhesive layer 96. In this case, there is a possibility that a minute gap will be formed by air entering between the cut face and the first transparent adhesive layer 95 and so forth, and that the cut face of the substrate 11 will be visually recognizable by the bare eye of the observer.

Conversely, according to the present embodiment, the surface roughness Ra of the third face 11c is 0.5 μm or less. Accordingly, air can be suppressed from entering in between the first transparent adhesive layer 95 and second transparent adhesive layer 96 and the third face 11c. Accordingly, the substrate 11 of the wiring board 10 can be made to be less visually recognizable when the observer observes the image display device 60 from the light-emitting face 64 side. In particular, in a case in which each of the first transparent adhesive layer 95 and the second transparent adhesive layer 96 has an area that is greater than the substrate 11, the outer edge of the substrate 11 can be made to be less visually recognizable by the bare eye of the observer, and thus keep the observer from recognizing the presence of the substrate 11.

Also, according to the present embodiment, the wiring board 10 includes the substrate 11, and the mesh wiring layer 20 disposed on the substrate 11. Also, the substrate 11 has transparency. Further, the mesh wiring layer 20 has a conductor portion serving as a formation portion of a non-transparent conductor layer, and a mesh-like pattern with a great number of openings. Accordingly, the transparency of the wiring board 10 is secured. Thus, when the wiring board 10 is disposed over the display device 61, the display device 61 can be visually recognized from the openings 23 of the mesh wiring layer 20, and visual recognition of the display device 61 is not impeded.

Further, according to the present embodiment, the first transparent adhesive layer 95 and the second transparent adhesive layer 96 each contains acrylic-based resin. Thus, the difference in the refractive index between the first transparent adhesive layer 95 and the second transparent adhesive layer 96 can be substantially done away with, and reflection of visible light at the interface B4 of the first transparent adhesive layer 95 and the second transparent adhesive layer 96 can be suppressed more reliably.

### EXAMPLES

Next, specific examples according to the present embodiment will be described.

### Example B1

An image display device laminate having the configuration illustrated in FIG. 18 was fabricated. In this case, a substrate made of polyethylene terephthalate, 40 μm thick, was used as the substrate of the wiring board. Also, an OCA layer made of acrylic resin, 50 μm thick, was used as the first transparent adhesive layer and the second transparent adhesive layer.

Also, the surface roughness Ra of the third face was 0.45 μm. At this time, the surface roughness Ra of the third face was measured by a method conforming to JIS B 0601-2013, using a laser microscope (VK-X250, manufactured by Keyence Corporation).

Next, a visibility evaluation test was performed. In the visibility evaluation test, ten subjects confirmed visibility of the wiring board on the image display device laminate. At this time, the effects of transmitted light on the visibility of the wiring board were confirmed.

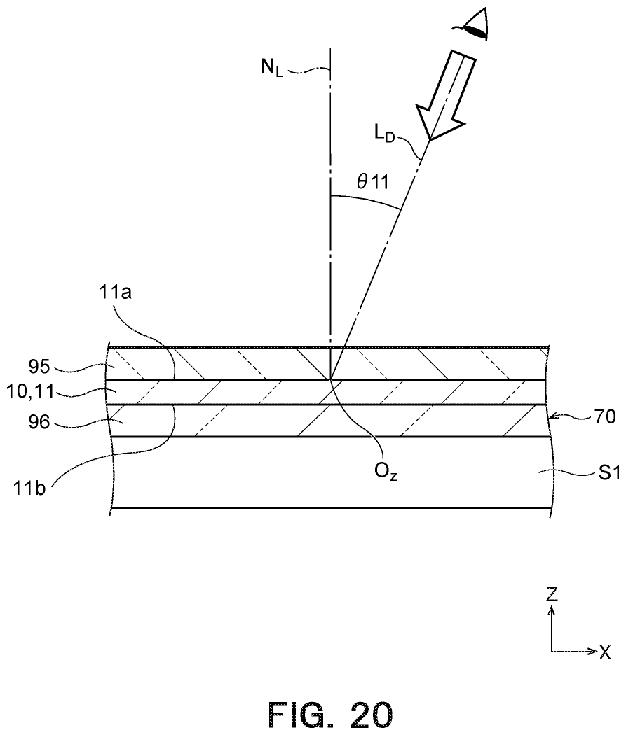

At the time of confirming the effects of transmitted light on the visibility of the wiring board, first, a light source (white light source) S1 having a luminance of 150 cd/m² was prepared, as illustrated in FIG. 20. Next, the image display device laminate 70 was disposed on the light source S1 so that the second transparent adhesive layer 96 faces the light source S1.

Next, the visibility of the wiring board 10 was confirmed. At this time, first, the image display device laminate 70 was illuminated by light from the light source S1. The visibility of the wiring board 10 was then confirmed in a state of being illuminated by the light. At this time, the visibility of the wiring board 10 was confirmed when viewing the image display device laminate 70 from a 150° viewing angle.

Now, the viewing angle is an angle of 2×θ11, where an angle formed between a normal line N_{L} perpendicular to the first face 11a of the substrate 11 and a line of sight L₀ directed toward an intersection O_{z} between the normal line N_{L} and the first face 11a of the substrate 11 is θ11, as illustrated in FIG. 20.

Also, the effects of reflected light on the visibility of the wiring board were confirmed.

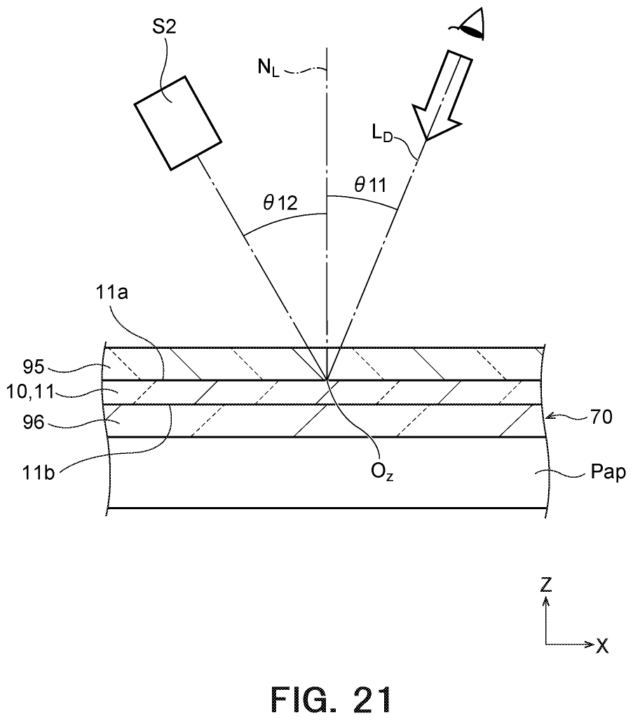

At the time of confirming the effects of transmitted light on the visibility of the wiring board, first, a black sheet of drawing paper Pap was prepared, as illustrated in FIG. 21. Next, the image display device laminate 70 was disposed on the drawing paper Pap so that the second transparent adhesive layer 96 faces the drawing paper Pap.

Also, a light source S2 having luminous intensity of 10,000 cd was prepared. The light source S2 was then disposed so that the light source S2 faces the first transparent adhesive layer 95.

Next, the visibility of the wiring board 10 was confirmed. At this time, first, the image display device laminate 70 was illuminated by light from the light source S2. The visibility of the wiring board 10 was then confirmed in the state of being illuminated by light. At this time, the visibility of the wiring board 10 when viewing the image display device laminate 70 from a 150° viewing angle was confirmed. At this time, an angle θ12 between the direction of illumination of light from the light source S2 and the normal line N_{L} was set to 30°, 60°, and 90°, and the visibility of the wiring board 10 was confirmed for each case.

### Example B2

An image display device laminate was fabricated in the same way as in Example B1, other than the thickness of the substrate being 25 μm, the thicknesses of the first transparent adhesive layer and the second transparent adhesive layer each being 40 μm, and the surface roughness Ra of the third face being 0.025 μm, and the visibility evaluation test was performed.

### Example B3

An image display device laminate was fabricated in the same way as in Example B1, other than the thickness of the substrate being 5 μm, the thicknesses of the first transparent adhesive layer and the second transparent adhesive layer each being 25 μm, and the surface roughness Ra of the third face being 0.1 μm, and the visibility evaluation test was performed.

### Example B4

An image display device laminate was fabricated in the same way as in Example B1, other than the thickness of the substrate being 60 μm, the thicknesses of the first transparent adhesive layer and the second transparent adhesive layer each being 50 μm, and the surface roughness Ra of the third face being 0.45 μm, and the visibility evaluation test was performed.

### Comparative Example B1

An image display device laminate was fabricated in the same way as in Example B1, other than the thickness of the substrate being 25 μm, the thicknesses of the first transparent adhesive layer and the second transparent adhesive layer each being 40 μm, and the surface roughness Ra of the third face being 1.2 μm, and the visibility evaluation test was performed.

Table 3 shows the results of the above. In the space of transmitted light in Table 3, “A (excellent)” means that two or less subjects out of ten were able to visually discern the outer shape of the wiring board. “B (good)” means that three or more and seven or less subjects out of ten were able to visually discern the outer shape of the wiring board. Also, “C (poor)” means that eight or more subjects out of ten were able to visually discern the outer shape of the wiring board.

Also, in the space of reflected light in Table 3, “A (excellent)” means that two or less subjects out of ten were able to visually discern the outer shape of the wiring board at each case of angles θ12 of 30°, 60°, and 90°. “B (good)” means that three or more and seven or less subjects out of ten were able to visually discern the outer shape of the wiring board at each case of angles θ12 of 30°, 60°, and 90°. Also, “C (poor)” means that eight or more subjects out of ten were able to visually discern the outer shape of the wiring board at each case of angles θ12 of 30°, 60°, and 90°.

TABLE 3

| | | Thickness | Thickness of | | | |
|---|---|---|---|---|---|---|
| | | of first | second | | | |
| | Thickness of | transparent | transparent | Surface | | |
| | substrate | adhesive layer | adhesive layer | roughness Ra | Transmitted | Reflected |
| | (μm) | (μm) | (μm) | (μm) | light | light |
| Example B1 | 40 | 50 | 50 | 0.45 | A | A |
| Example B2 | 25 | 40 | 40 | 0.025 | A | A |
| Example B3 | 5 | 25 | 25 | 0.1 | A | A |
| Example B4 | 60 | 50 | 50 | 0.45 | B | B |
| Comparative | 25 | 40 | 40 | 1.2 | C | C |
| Example B1 | | | | | | |

As a result, as shown in Table 3, with the image display device laminate according to Comparative Example B1, the outer shape of the wiring board was in a state of being readily visually discernable. Conversely, with the image display device laminates according to Example B1 to Example B4, the outer shape of the wiring board was in a state of being less visually discernable. In particular, with the image display device laminates according to Example B1 to Example B3, two or less subjects out of ten were able to visually discern the outer shape of the wiring board in each case of angles θ12 of 30°, 60°, and 90°. Accordingly, it was found that with the image display device laminate according to the present embodiment, the wiring board could be made to be less visually recognizable by the bare eye.

### Third Embodiment

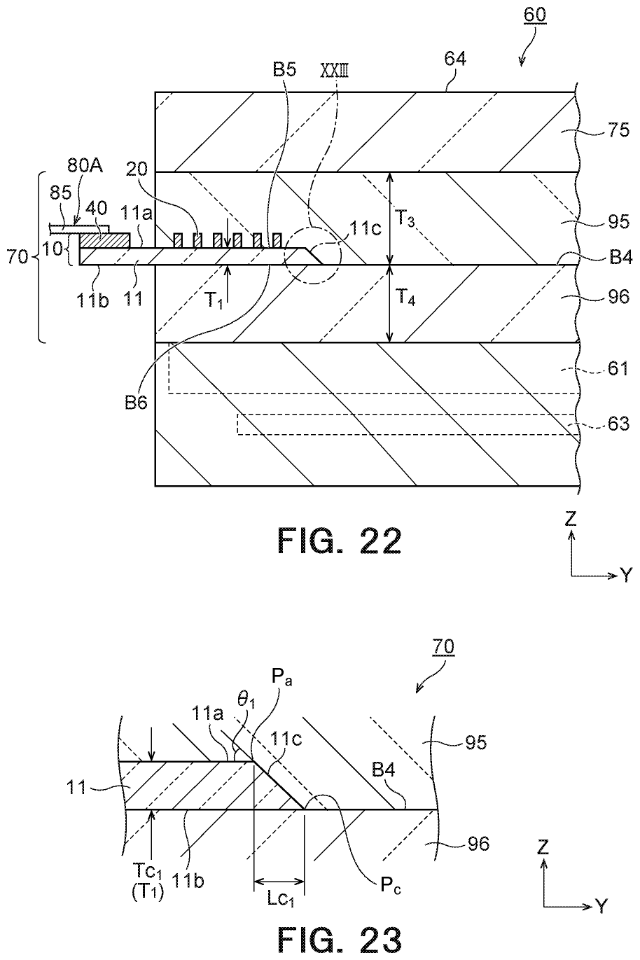

Next, a third embodiment will be described with reference to FIG. 22 to FIG. 24. FIG. 22 to FIG. 24 are diagrams illustrating the second embodiment. In FIG. 22 to FIG. 24, portions that are the same as those of the first embodiment illustrated in FIG. 1 to FIG. 16 or portions that are the same as those of the second embodiment illustrated in FIG. 17 to FIG. 21 may be denoted by the same symbols, and detailed description omitted.

### [Configuration of Image Display Device]

First, the configuration of the image display device according to the present embodiment will be described with reference to FIG. 22 and FIG. 23.

As illustrated in FIG. 22 and FIG. 23, the image display device 60 according to the present embodiment includes the image display device laminate 70, and the display device (display) 61 that is laminated on the image display device laminate 70. Of these, the image display device laminate 70 includes the first transparent adhesive layer (first adhesive layer) 95, the second transparent adhesive layer (second adhesive layer) 96, and the wiring board 10. Of these, the wiring board 10 has the substrate 11 and the mesh wiring layer 20. The substrate 11 includes the first face 11a, the second face 11b that is situated on the opposite side from the first face 11a, and the third face 11c that is situated between the first face 11a and the second face 11b. The mesh wiring layer 20 is disposed on the first face 11a of the substrate 11. Also, the power supply unit 40 is electrically connected to the mesh wiring layer 20. Also, the communication module 63 is disposed on the minus side of the display device 61 in the Z direction. The image display device laminate 70, the display device 61, and the communication module 63 are accommodated in the housing 62. Further, in the present embodiment as well, the wiring board 10 and the power supply line 85 electrically connected to the wiring board 10 make up the module 80A. In other words, the module 80A includes the above-described wiring board 10, and the power supply line 85 that is electrically connected to the power supply unit 40. When the module 80A is assembled into the image display device 60 that has the display device 61, the power supply unit 40 of the wiring board 10 is electrically connected to the communication module 63 of the image display device 60 via the power supply line 85.

Now, as described above, the substrate 11 includes the first face 11a, the second face 11b that is situated on the opposite side from the first face 11a, and the third face 11c that is situated between the first face 11a and the second face 11b. In this case, the third face 11c of the substrate 11 is covered by the first adhesive layer 95, as illustrated in FIG. 23.

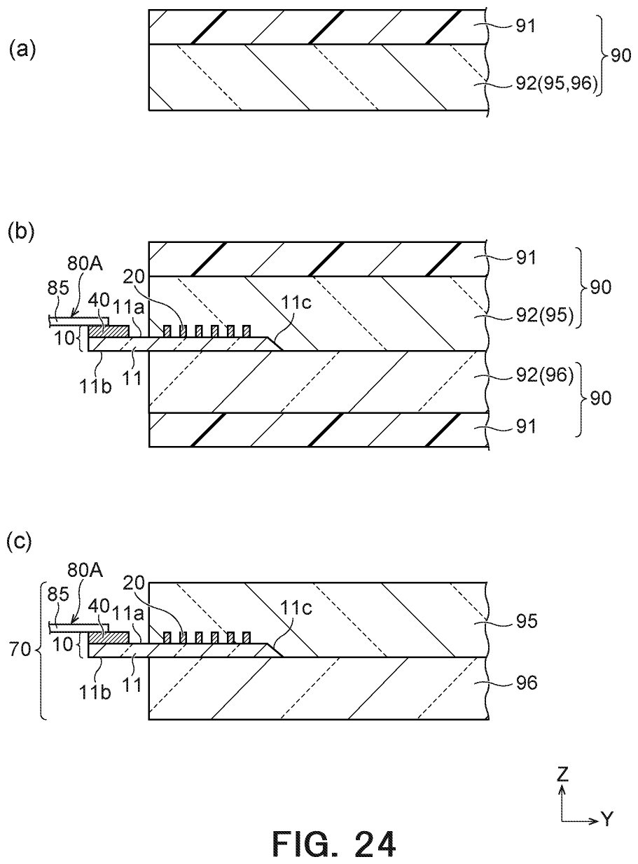

In the present embodiment, the third face 11c is inclined as to the first face 11a in a cross-section taken in the direction (Z direction) normal to the first face 11a. In the present embodiment, the third face 11c is inclined toward an outer side from the first face 11a toward the second face 11b. In the example that is illustrated, the third face 11c is inclined to a plus side in the Y direction, toward the minus side in the Z direction. Also, the third face 11c is inclined at a predetermined inclination angle θ₁ as to the first face 11a, from the first face 11a to the second face 11b. Air can thus be suppressed from entering between the first transparent adhesive layer 95 and the third face 11c due to the third face 11c being inclined as to the first face 11a in a cross-section taken in the direction (Z direction) normal to the first face 11a. That is to say, at the time of holding the wiring board 10 between the OCA layers 92 (see FIG. 24(b)), air that has entered between the OCA layers 92 and the third face 11c can be shunted to the outside more easily, which will be described later. Accordingly, air can be suppressed from entering between the first transparent adhesive layer 95 and the third face 11c. Note that in the present specification, “outer side” refers to a side going away from the center of the first face 11a in the X direction or the Y direction.

Now, in a cross-section taken in the direction (Z direction) normal to the first face 11a, a length L_{c1} in the direction (Y direction) orthogonal to the direction normal to the first face 11a, between a portion P_{c} situated on the outermost side of the third face 11c and a portion Pₐ situated on the outermost side of the first face 11a may be 0.15 times or more to 2 times or less a length T_{c1} between the portion P_{c} and the portion Pₐ in the direction normal to the first face 11a. Due to the length L_{c1} being 0.15 times or more the length T_{c1}, the inclination angle θ1 of the third face 11c as to the first face 11a can be made to be smaller. Accordingly, air can be suppressed from entering between the first transparent adhesive layer 95 and the third face 11c even more effectively. Also, due to the length L_{c1} being 2 times or less the length T_{c1}, formability of the substrate 11 can be improved. Now, the substrate 11 is cut into a desired size in the process of fabricating the wiring board 10, which will be described later. The third face 11c is formed from the cutting face at the time of cutting the substrate 11. Accordingly, cutting of the substrate 11 can be suppressed from becoming difficult due to the length L_{c1} being 2 times or less the length T_{c1}. As a result, the formability of the substrate 11 can be improved. In this case, the inclination angle θ₁ is preferably 26.5° or more and 81.5° or less. Note that, as described above, the third face 11c inclines as to the first face 11a at a predetermined inclined angle, from the first face 11a to the second face 11b. Accordingly, in the example that is illustrated, the length T_{c1} is equal to a thickness T₁ of the substrate 11.

Also, in the cross-section taken in the direction (Z direction) normal to the first face 11a, the third face 11c heads to the outer side the closer toward the interface B4 between the first adhesive layer 95 and the second adhesive layer 96. Accordingly, air can be suppressed from entering between the first transparent adhesive layer 95 and the third face 11c even more effectively. That is to say, at the time of holding the wiring board 10 by the OCA layers 92, air that has entered between the OCA layers 92 and the third face 11c can be shunted to the outside more easily.

As described above, the image display device laminate 70 is made up of the wiring board 10, the first transparent adhesive layer 95 that has a greater area than the substrate 11 of the wiring board 10, and the second transparent adhesive layer 96 that has a greater area than the substrate 11. Such an image display device laminate 70 is also provided in the present embodiment.

### [Manufacturing Method of Image Display Device Laminate]

Next, a manufacturing method of the image display device laminate 70 according to the present embodiment will be described.

First, the wiring board 10 is fabricated by the method illustrated in FIGS. 7(a) to 7(f), for example. Thereafter, the wiring board 10 is cut into a desired size. At this time, the wiring board 10 may be cut into the desired size by a blade heated to 100° C. or higher and 300° C. or lower, laser, etching, or the like, for example. Thus, the surface roughness of the cut face (i.e., third face 11c) can be suppressed from increasing as compared to a case of cutting the wiring board 10 using an unheated blade, for example.

Next, the first transparent adhesive layer 95, the wiring board 10, and the second transparent adhesive layer 96 are laminated on each other. At this time, first, as illustrated in FIG. 24(a), the OCA sheet 90 is prepared that includes, for example, the release film 91 of polyethylene terephthalate (PET), and the OCA layer 92 (first transparent adhesive layer 95 or second transparent adhesive layer 96) laminated on the release film 91. At this time, the OCA layer 92 may be a layer obtained by coating a curable adhesive layer composition that is in a liquid state and that includes a polymerizable compound, on the release film 91, and then cured by using ultraviolet rays (UV) or the like, for example. This curable adhesive layer composition contains a polar-group-containing monomer.

Next, the OCA layers 92 of the OCA sheets 90 are applied to the wiring board 10, as illustrated in FIG. 24(b). At this time, the power supply line 85 is first electrically connected to the power supply unit 40. At this time, the power supply line 85 is pressure-bonded to the wiring board 10 across an anisotropic conductive film that is not illustrated, for example. At this time, the power supply line 85 is pressure-bonded to the wiring board 10 by applying pressure and heat to the power supply line 85. Thus, the power supply line 85 is electrically connected to the power supply unit 40. In this way, the module 80A including the wiring board 10, and the power supply line 85 electrically connected to the power supply unit 40, is obtained.

Next, the OCA layers 92 of the OCA sheets 90 are applied to the wiring board 10. Thus, the wiring board 10 is held by the OCA layers 92.

Thereafter, as illustrated in FIG. 24(c), the release films 91 are removed by separation from the OCA layers 92 of the OCA sheets 90 applied to the wiring board 10, thereby obtaining the first transparent adhesive layer 95 (OCA layer 92), the wiring board 10, and the second transparent adhesive layer 96 (OCA layer 92), which are laminated on each other.

Thus, the image display device laminate 70 including the first transparent adhesive layer 95, the second transparent adhesive layer 96, and the wiring board 10 is obtained.

Thereafter, the display device 61 is laminated on the image display device laminate 70, thereby obtaining the image display device 60 including the image display device laminate 70 and the display device 61 laminated on the image display device laminate 70.

### Effects of Present Embodiment

Next, the effects of the present embodiment having such a configuration will be described.

As illustrated in FIG. 22 and FIG. 23, the wiring board 10 is assembled into the image display device 60 that has the display device 61. At this time, the wiring board 10 is disposed above the display device 61. The mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

According to the present embodiment, a partial region of the substrate 11 is disposed in a partial region between the first transparent adhesive layer 95 and the second transparent adhesive layer 96. Also, the third face 11c of the substrate 11 is covered by the first adhesive layer 95. Further, the third face 11c inclines to the outer side from the first face 11a toward the second face 11b. Due to the third face 11c inclining to the outer side from the first face 11a toward the second face 11b in this way, air can be suppressed from entering between the first transparent adhesive layer 95 and the third face 11c.

Now, as described above, after the mesh wiring layer 20 is provided on the substrate 11, the wiring board 10 is cut into a desired size. At this time, there is concern that the surface roughness Ra of the cut face (i.e., third face) of the substrate 11 will increase. In a case in which the surface roughness of the cut face increases, there are cases in which air enters in between this cut face and the first transparent adhesive layer 95. In this case, there is a possibility that a minute gap will be formed by air entering between the cut face and the first transparent adhesive layer 95 and so forth, and that the cut face of the substrate 11 may be readily visually recognizable by the bare eye of the observer.

Conversely, according to the present embodiment, the third face 11c inclines to the outer side from the first face 11a toward the second face 11b. Accordingly, air entering between the OCA layers 92 and the third face 11c at the time of holding the wiring board 10 by the OCA layers 92 can be shunted to the outside more easily. Thus, air can be suppressed from entering between the first transparent adhesive layer 95 and the third face 11c. As a result, the substrate 11 of the wiring board 10 can be made to be less visually recognizable by the bare eye when the observer observes the image display device 60 from the light-emitting face 64 side. In particular, in a case in which each of the first transparent adhesive layer 95 and the second transparent adhesive layer 96 has an area that is greater than the substrate 11, the outer edge of the substrate 11 can be made to be less visually recognizable by the bare eye of the observer, and thus keep the observer from recognizing the presence of the substrate 11.

Also, according to the present embodiment, the wiring board 10 includes the substrate 11, and the mesh wiring layer 20 disposed on the substrate 11. Also, the substrate 11 has transparency. Further, the mesh wiring layer 20 has a conductor portion serving as a formation portion of a non-transparent conductor layer, and a mesh-like pattern with a great number of openings. Accordingly, the transparency of the wiring board 10 is secured. Thus, when the wiring board 10 is disposed over the display device 61, the display device 61 can be visually recognized from the openings 23 of the mesh wiring layer 20, and visual recognition of the display device 61 is not impeded.

Also, according to the present embodiment, in the cross-section taken in the direction (Z direction) normal to the first face 11a, the third face 11c heads to the outer side the closer toward the interface B4 between the first adhesive layer 95 and the second adhesive layer 96. Accordingly, air can be suppressed from entering between the first transparent adhesive layer 95 and the third face 11c even more effectively. That is to say, at the time of holding the wiring board 10 by the OCA layers 92, air that has entered between the OCA layers 92 and the third face 11c can be shunted to the outside even more easily.

Further, according to the present embodiment, the first transparent adhesive layer 95 and the second transparent adhesive layer 96 each contain acrylic-based resin. Thus, the difference in the refractive index between the first transparent adhesive layer 95 and the second transparent adhesive layer 96 can be substantially done away with, and reflection of visible light at the interface B4 between the first transparent adhesive layer 95 and the second transparent adhesive layer 96 can be suppressed more reliably.

Further, according to the present embodiment, the thickness T₃ of the first transparent adhesive layer 95 is greater than the thickness T₄ of the second transparent adhesive layer 96. Accordingly, unevenness due to the mesh wiring layer 20 can be suppressed from being formed on the surface of the first transparent adhesive layer 95, and thus the surface of the first transparent adhesive layer 95 can be made to be smooth.

### MODIFICATIONS

Next, modifications of the image display device laminate 70 will be described.

### First Modification

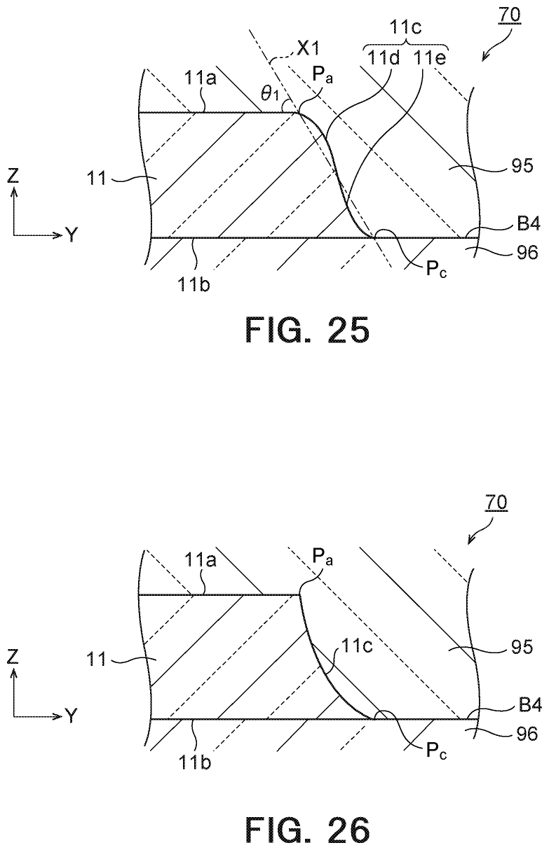

FIG. 25 illustrates a modification of the image display device laminate. The modification illustrated in FIG. 25 differs with respect to the point that the third face 11c is curved in the cross-section taken in the direction (Z direction) normal to the first face 11a, and other configurations are substantially the same as those of the form illustrated in FIG. 22 to FIG. 24 described above. In FIG. 25, portions that are the same as in the embodiment illustrated in FIG. 22 to FIG. 24 are denoted by the same symbols, and detailed description will be omitted.

In the modification illustrated in FIG. 25, the third face 11c is curved in the cross-section taken in the direction (Z direction) normal to the first face 11a. In the present modification, the third face 11c includes a first curved portion 11d that is convex toward the outer side, and a second curved portion 11e that is convex toward the inner side. The first curved portion 11d and the second curved portion 11e are interconnected to each other. Also, the first curved portion 11d is interconnected to the first face 11a, and the second curved portion 11e is interconnected to the second face 11b.

The first curved portion 11d and the second curved portion 11e each heads toward the outer side the closer toward the interface B4 between the first adhesive layer 95 and the second adhesive layer 96. Thus, air can be suppressed from entering between the first transparent adhesive layer 95 and the third face 11c even more effectively. In a case of forming such a third face 11c, the wiring board 10 is preferably cut to the desired size by laser or a heated metal blade.

Now, in a case in which the third face 11c is curved, the inclination angle θ₁ of the third face 11c as to the first face 11a may be an angle formed between an imaginary line X1 connecting the portion P_{c} and the portion Pₐ, and the first face 11a, in the cross-section taken in the direction (Z direction) normal to the first face 11a.

In the present modification as well, air can be suppressed from entering between the first transparent adhesive layer 95 and the third face 11c. Thus, the substrate 11 of the wiring board 10 can be made to be less visually recognizable by the bare eye.

### Second Modification

FIG. 26 illustrates a second modification of the image display device laminate. The modification illustrated in FIG. 26 differs with respect to the point that the third face 11c includes neither the first curved portion 11d nor the second curved portion 11e in the cross-section taken in the direction normal to the first face 11a, and other configurations are substantially the same as those of the form illustrated in FIG. 25 described above. In FIG. 26, portions that are the same as in the embodiment illustrated in FIG. 25 are denoted by the same symbols, and detailed description will be omitted.

In the second modification illustrated in FIG. 26, the third face 11c is curved in the cross-section taken in the direction (Z direction) normal to the first face 11a. In the present modification, the third face 11c is curved so as to be convex toward the inner side. In this case as well, at the time of holding the wiring board 10 by the OCA layers 92, air that has entered between the OCA layers 92 and the third face 11c can be shunted to the outside more easily. Accordingly, air can be suppressed from entering between the first transparent adhesive layer 95 and the third face 11c.

### Third Modification

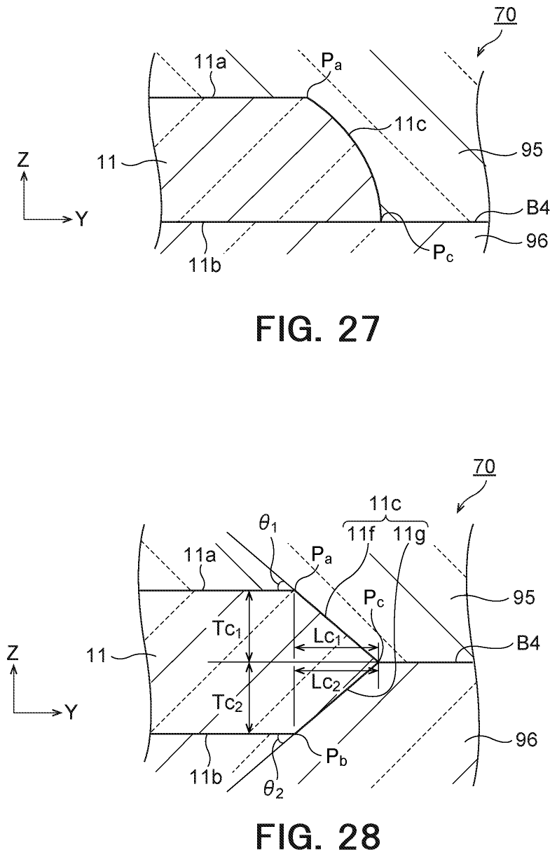

FIG. 27 illustrates a third modification of the image display device laminate. The modification illustrated in FIG. 27 differs with respect to the point that the third face 11c is curved toward the outer side in the cross-section taken in the direction normal to the first face 11a, and other configurations are substantially the same as those of the form illustrated in FIG. 26 described above. In FIG. 27, portions that are the same as in the form illustrated in FIG. 26 are denoted by the same symbols, and detailed description will be omitted.

In the third modification illustrated in FIG. 27, the third face 11c is curved in the cross-section taken in the direction (Z direction) normal to the first face 11a, so as to be convex toward the outer side. In this case as well, at the time of holding the wiring board 10 by the OCA layers 92, air that has entered between the OCA layers 92 and the third face 11c can be shunted to the outside more easily. Accordingly, air can be suppressed from entering between the first transparent adhesive layer 95 and the third face 11c.

### Fourth Modification

FIG. 28 illustrates a fourth modification of the image display device laminate. The modification illustrated in FIG. 28 differs with respect to the point of the third face 11c including a first portion 11f that is interconnected to the first face 11a and a second portion 11g that is interconnected to the second face 11b, and other configurations are substantially the same as those of the form illustrated in FIG. 22 to FIG. 24 described above. In FIG. 28, portions that are the same as in the form illustrated in FIG. 22 to FIG. 24 are denoted by the same symbols, and detailed description will be omitted.

In the fourth modification illustrated in FIG. 28, the third face 11c includes the first portion 11f that is interconnected to the first face 11a and the second portion 11g that is interconnected to the second face 11b. The first portion 11f is covered by the first transparent adhesive layer 95. On the other hand, the second portion 11g is covered by the second transparent adhesive layer 96. The first portion 11f and the second portion 11g are interconnected to each other.

The first portion 11f and the second portion 11g each extend linearly in the cross-section taken in the direction (Z direction) normal to the first face 11a. Also, the first portion 11f and the second portion 11g are non-parallel in the cross-section taken in the direction (Z direction) normal to the first face 11a. In the cross-section taken in the direction (Z direction) normal to the first face 11a, the first portion 11f and the second portion 11g each heads toward the outer side the closer to the interface B4 between the first adhesive layer 95 and the second adhesive layer 96. In the example that is illustrated, the first portion 11f inclines to the plus side in the Y direction, toward the minus side in the Z direction. On the other hand, the second portion 11g inclines to the plus side in the Y direction, toward the plus side in the Z direction. Due to the first portion 11f and the second portion 11g thus heading toward the outer side toward the interface B4 between the first adhesive layer 95 and the second adhesive layer 96 in the cross-section taken in the direction (Z direction) normal to the first face 11a, air can be suppressed from entering between the first transparent adhesive layer 95 or second transparent adhesive layer 96 and the third face 11c even more effectively. In a case of forming such a third face 11c, the wiring board 10 is preferably cut to the desired size by laser or a heated metal blade.

In the present modification, the portion P_{c} that is situated on the outermost side of the third face 11c is between the first face 11a and the second face 11b in the cross-section taken in the direction (Z direction) normal to the first face 11a. In this case, a length L_{c2} between the portion P_{c} situated on the outermost side of the third face 11c and a portion P_{b} situated on the outermost side of the second face 11b, in the direction (Y direction) that is orthogonal to the direction normal to the first face 11a, may be 0.15 times or more and 2 times or less a length T_{c2} between the portion P_{c} and the portion P_{b} in the direction normal to the first face 11a. Due to the length L_{c2} being 0.15 times or more the length T_{c2}, an inclination angle θ₂ of the third face 11c as to the second face 11b can be made to be small. Accordingly, air can be suppressed from entering between the second transparent adhesive layer 96 and the third face 11c even more effectively. Also, due to the length L_{c2} being 2 times or less the length T_{c2}, the formability of the substrate 11 can be improved. In this case, the inclination angle θ₂ is preferably 26.5° or more and 81.5° or less. Note that in the present modification, the length L_{c2} is equal to the length L_{c1} described above.

According to the present modification, air can be suppressed from entering between the first transparent adhesive layer 95 or second transparent adhesive layer 96 and the third face 11c. Thus, the substrate 11 of the wiring board 10 can be made to be less visually recognizable by the bare eye.

### Fifth Modification

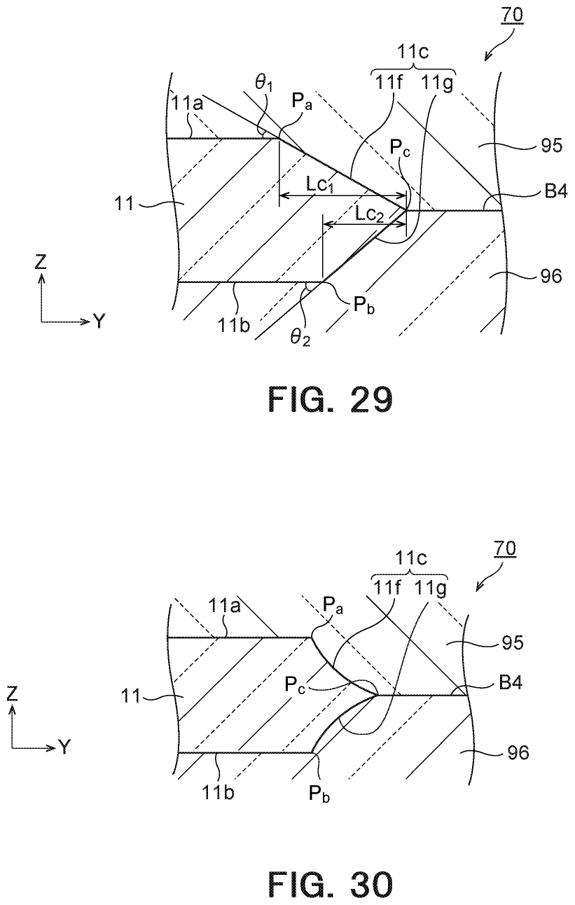

FIG. 29 illustrates a fifth modification of the image display device laminate. The modification illustrated in FIG. 29 differs with respect to the point that the length L_{c1} and the length L_{c2} differ from each other, and other configurations are substantially the same as those of the form illustrated in FIG. 28 described above. In FIG. 29, portions that are the same as in the form illustrated in FIG. 28 are denoted by the same symbols, and detailed description will be omitted.

In the fifth modification illustrated in FIG. 29, the length L_{c1} and the length L_{c2} differ from each other. In the present modification, the length L_{c2} is shorter than the length L_{c1}. Accordingly, the inclination angle θ₁ of the third face 11c as to the first face 11a is smaller than the inclination angle θ₂ of the third face 11c as to the second face 11b.

In the present modification as well, air can be suppressed from entering between the first transparent adhesive layer 95 or second transparent adhesive layer 96 and the third face 11c. Thus, the substrate 11 of the wiring board 10 can be made to be less visually recognizable by the bare eye.

### Sixth Modification

FIG. 30 illustrates a sixth modification of the image display device laminate. The modification illustrated in FIG. 30 differs with respect to the point that the first portion 11f and the second portion 11g are each curved in the cross-section taken in the direction normal to the first face 11a, and other configurations are the same as those of the form illustrated in FIG. 28 described above. In FIG. 30, portions that are the same as in the form illustrated in FIG. 28 are denoted by the same symbols, and detailed description will be omitted.

In the sixth modification illustrated in FIG. 30, the first portion 11f and the second portion 11g are each curved in the cross-section taken in the direction (Z direction) normal to the first face 11a. In the present modification, the first portion 11f and the second portion 11g are each curved so as to be convex toward the inner side in the cross-section taken in the direction (Z direction) normal to the first face 11a. In this case as well, at the time of holding the wiring board 10 by the OCA layers 92, air that has entered between the OCA layers 92 and the third face 11c can be shunted to the outside more easily. Accordingly, air can be suppressed from entering between the first transparent adhesive layer 95 or second transparent adhesive layer 96 and the third face 11c.

### Seventh Modification

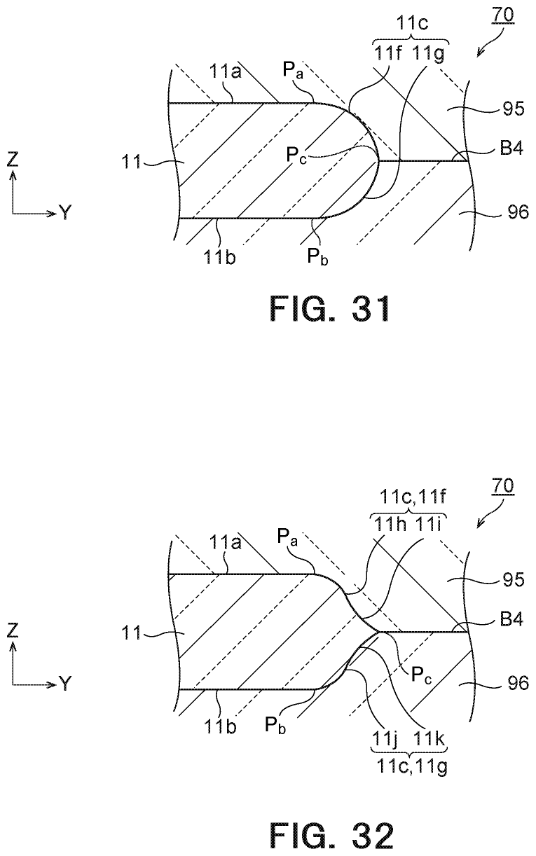

FIG. 31 illustrates a seventh modification of the image display device laminate. The modification illustrated in FIG. 31 differs with respect to the point that the first portion 11f and the second portion 11g are each curved so as to be convex toward the outer side in the cross-section taken in the direction (Z direction) normal to the first face 11a, and other configurations are substantially the same as those of the form illustrated in FIG. 30 described above. In FIG. 31, portions that are the same as in the form illustrated in FIG. 30 are denoted by the same symbols, and detailed description will be omitted.

In the seventh modification illustrated in FIG. 31, the first portion 11f and the second portion 11g are each curved so as to be convex toward the outer side in the cross-section taken in the direction (Z direction) normal to the first face 11a.

According to the present modification as well, air can be suppressed from entering between the first transparent adhesive layer 95 or second transparent adhesive layer 96 and the third face 11c. Thus, the substrate 11 of the wiring board 10 can be made to be less visually recognizable by the bare eye.

### Eighth Modification

FIG. 32 illustrates an eighth modification of the image display device laminate. The modification illustrated in FIG. 32 differs with respect to the point that the first portion 11f includes a third curved portion 11h that is convex toward the outer side, and a fourth curved portion 11i that is convex toward the inner side, in the cross-section taken in the direction (Z direction) normal to the first face 11a, and other configurations are substantially the same as those of the form illustrated in FIG. 30 described above. In FIG. 32, portions that are the same as in the form illustrated in FIG. 30 are denoted by the same symbols, and detailed description will be omitted.

In the modification illustrated in FIG. 32, in the cross-section taken in the direction (Z direction) normal to the first face 11a, the first portion 11f includes the third curved portion 11h that is convex toward the outer side and the fourth curved portion 11i that is convex toward the inner side. The third curved portion 11h is interconnected to the first face 11a, and the fourth curved portion 11i is interconnected to the third curved portion 11h.

Also, the second portion 11g includes a fifth curved portion 11j that is convex toward the outer side and a sixth curved portion 11k that is convex toward the inner side. The fifth curved portion 11j is interconnected to the second face 11b, and the sixth curved portion 11k is interconnected to the fourth curved portion 11i and the fifth curved portion 11j.

The third curved portion 11h, the fourth curved portion 11i, the fifth curved portion 11j, and the sixth curved portion 11k each heads toward the outer side, the closer toward the interface B4 between the first adhesive layer 95 and the second adhesive layer 96. Accordingly, air can be suppressed even more effectively from entering between the first transparent adhesive layer 95 or second transparent adhesive layer 96, and the third face 11c.

According to the present modification as well, air can be suppressed from entering between the first transparent adhesive layer 95 or second transparent adhesive layer 96 and the third face 11c. Thus, the substrate 11 of the wiring board 10 can be made to be less visually recognizable by the bare eye.

### EXAMPLES

Next, specific examples according to the present embodiment will be described.

### Example C1

An image display device laminate having the configuration illustrated in FIG. 22 was fabricated. In this case, a substrate made of polyethylene terephthalate, 40 μm thick, was used as the substrate of the wiring board. Also, an OCA layer made of acrylic resin, 50 μm thick, was used as the first transparent adhesive layer. Further, an OCA layer made of acrylic resin, 25 μm thick, was used as the second transparent adhesive layer. At this time, the inclination angle θ₁ of the third face as to the first face was 75°.

Next, a visibility evaluation test was performed. In the visibility evaluation test, ten subjects confirmed visibility of the wiring board on the image display device laminate. At this time, the effects of transmitted light on the visibility of the wiring board were confirmed.

At the time of confirming the effects of transmitted light on the visibility of the wiring board, first, the light source (white light source) S1 having a luminance of 150 cd/m² was prepared, as illustrated in FIG. 20 described above. Next, the image display device laminate 70 was disposed on the light source S1 so that the second transparent adhesive layer 96 faces the light source S1.

Next, the visibility of the wiring board 10 was confirmed. At this time, first, the image display device laminate 70 was illuminated by light from the light source S1. At this time, the visibility of the wiring board 10 was confirmed in a state of being illuminated by the light. At this time, the visibility of the wiring board 10 was confirmed when viewing the image display device laminate 70 from a 150° viewing angle.

Now, as described earlier, the viewing angle is an angle of 2×θ11, where an angle formed between the normal line N_{L} perpendicular to the first face 11a of the substrate 11 and the line of sight L_{D} directed toward the intersection O_{z} between the normal line N_{L} and the first face 11a of the substrate 11 is θ11, as illustrated in FIG. 20.

Also, the effects of reflected light on the visibility of the wiring board were confirmed.

At the time of confirming the effects of transmitted light on the visibility of the wiring board, first, a black sheet of drawing paper Pap was prepared, as illustrated in FIG. 21 described above. Next, the image display device laminate 70 was disposed on the drawing paper Pap so that the second transparent adhesive layer 96 faces the drawing paper Pap.

Also, the light source S2 having luminous intensity of 10,000 cd was prepared. The light source S2 was then disposed so that the light source S2 faces the first transparent adhesive layer 95.

Next, the visibility of the wiring board 10 was confirmed. At this time, first, the image display device laminate 70 was illuminated by light from the light source S2. The visibility of the wiring board 10 was then confirmed in the state of being illuminated by light. At this time, the visibility of the wiring board 10 when viewing the image display device laminate 70 from a 150° viewing angle was confirmed. At this time, the angle θ12 between the direction of illumination of light from the light source S2 and the normal line N_{L} was set to 30°, 60°, and 90°, and the visibility of the wiring board 10 was confirmed for each case.

### Example C2

An image display device laminate was fabricated in the same way as Example C1, other than the thickness of the substrate being 25 μm, the thickness of the first transparent adhesive layer being 40 μm, the thickness of the second transparent adhesive layer being 20 μm, and the inclination angle θ₁ being 30°, and visibility was confirmed.

### Example C3

An image display device laminate was fabricated in the same way as Example C1, other than the thickness of the substrate being 5 μm, the thickness of the first transparent adhesive layer being 25 μm, the thickness of the second transparent adhesive layer being 12.5 μm, and the inclination angle θ₁ being 45°, and visibility was confirmed.

### Comparative Example C1

An image display device laminate was fabricated in the same way as Example C1, other than the thickness of the substrate being 25 μm, the thickness of the first transparent adhesive layer being 40 μm, the thickness of the second transparent adhesive layer being 20 μm, and the inclination angle θ₁ being 82°, and visibility was confirmed.

### Comparative Example C2

An image display device laminate was fabricated in the same way as Example C1, other than the thickness of the substrate being 50 μm, the thickness of the first transparent adhesive layer being 50 μm, the thickness of the second transparent adhesive layer being 25 μm, and the inclination angle θ₁ being 88°, and visibility was confirmed.

Table 4 shows the results of the above. In the space of transmitted light in Table 4, “A (good)” means that two or less subjects out of ten were able to visually discern the outer shape of the wiring board. Also, “C (poor)” means that eight or more subjects out of ten were able to visually discern the outer shape of the wiring board.

Also, in the space of reflected light in Table 4, “A (good)” means that two or less subjects out of ten were able to visually discern the outer shape of the wiring board at each case of angles θ12 of 30°, 60°, and 90°. Also, “C (poor)” means that eight or more subjects out of ten were able to visually discern the outer shape of the wiring board at each case of angles θ12 of 30°, 60°, and 90°.

TABLE 4

| | | Thickness | Thickness of | | | |
|---|---|---|---|---|---|---|
| | | of first | second | | | |
| | Thickness of | transparent | transparent | Inclination angle | | |
| | substrate | adhesive layer | adhesive layer | θ₁ | Transmitted | Reflected |
| | (μm) | (μm) | (μm) | (°) | light | light |
| Example C1 | 40 | 50 | 25 | 75 | A | A |
| Example C2 | 25 | 40 | 20 | 30 | A | A |
| Example C3 | 5 | 25 | 12.5 | 45 | A | A |
| Comparative | 25 | 40 | 20 | 82 | C | C |
| Example C1 | | | | | | |
| Comparative | 50 | 50 | 25 | 88 | C | C |
| Example C2 | | | | | | |

As a result, as shown in Table 4, with the image display device laminates according to Comparative Example C1 and Comparative Example C2, the outer shape of the wiring board was in a state of being readily visually discernable. Conversely, with the image display device laminates according to Example C1 to Example C3, the outer shape of the wiring board was in a state of being less visually discernable. Accordingly, it was found that with the image display device laminate according to the present embodiment, the wiring board could be made to be less visually recognizable by the bare eye.

### Fourth Embodiment

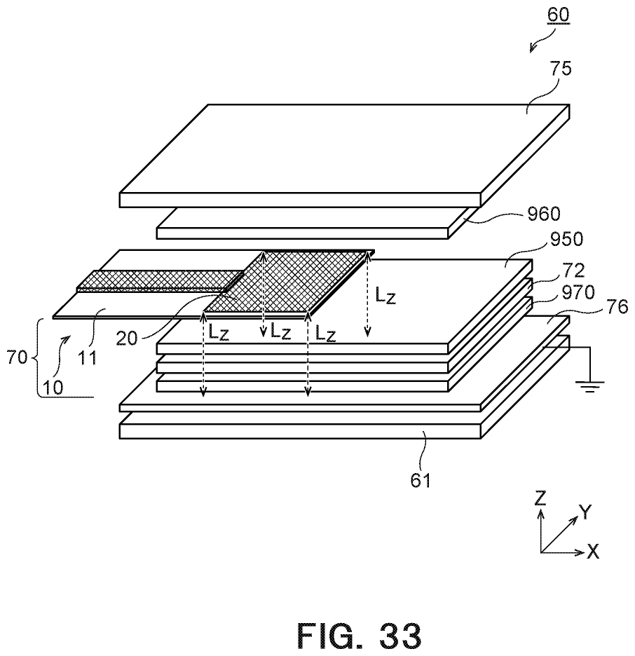

Next, a fourth embodiment will be described with reference to FIG. 33 to FIG. 35. FIG. 33 to FIG. 35 are diagrams illustrating the fourth embodiment. In FIG. 33 to FIG. 35, portions that are the same as those of the first embodiment illustrated in FIG. 1 to FIG. 16, portions that are the same as those of the second embodiment illustrated in FIG. 17 to FIG. 21, or portions that are the same as those of the third embodiment illustrated in FIG. 22 to FIG. 32 may be denoted by the same symbols, and detailed description omitted.

### [Configuration of Image Display Device and Image Display Device Laminate]

First, the configuration of the image display device and the image display device laminate according to the present embodiment will be described with reference to FIG. 33 to FIG. 35.

As illustrated in FIG. 33 to FIG. 35, the image display device 60 according to the present embodiment includes the image display device laminate 70, and the display device (display) 61 that is laminated on the image display device laminate 70. Of these, the image display device laminate 70 includes the wiring board 10, a conductive layer 76, and a third adhesive layer 950. The third adhesive layer 950 is situated between the wiring board 10 and the conductive layer 76. The wiring board 10 has the substrate 11 that has transparency, and the mesh wiring layer 20 that is disposed on the substrate 11. Also, the power supply unit 40 is electrically connected to the mesh wiring layer 20. In the present embodiment, a shortest distance between the mesh wiring layer 20 and the conductive layer 76 in the direction normal to the conductive layer 76 is L_{zmin}. Also, a longest distance between the mesh wiring layer 20 and the conductive layer 76 in the direction normal to the conductive layer 76 is L_{zmax}. At this time, L_{zmin}≥0.9 L_{zmax} holds.

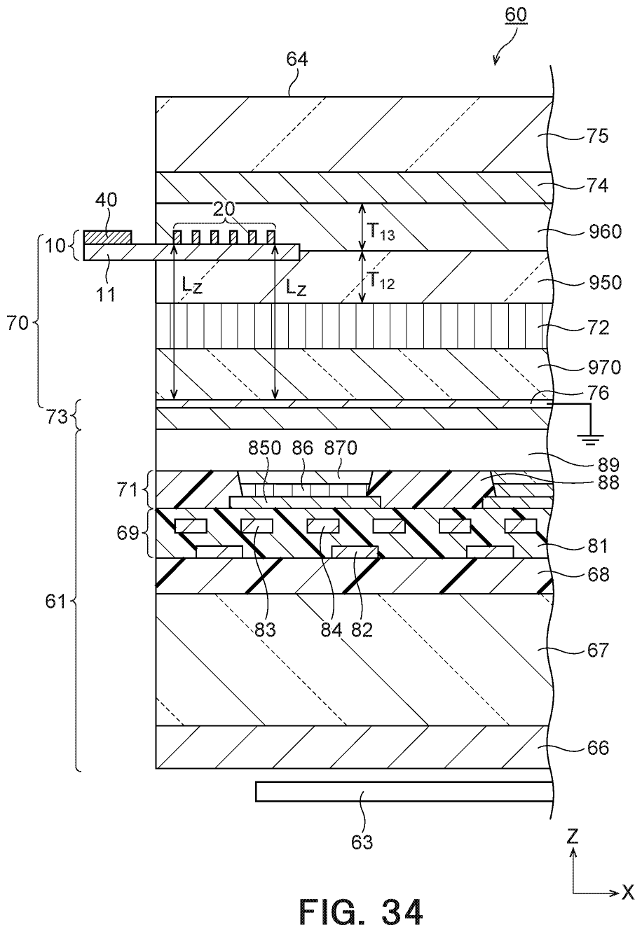

Also, the communication module 63 is disposed on the minus side of the display device 61 in the Z direction (see FIG. 34). The image display device laminate 70, the display device 61, and the communication module 63 are accommodated in the housing 62.

The display device 61 is made up of an organic EL (Electro Luminescence) display device, for example. The display device 61 includes, in order from an opposite side of the light-emitting face 64 (minus side in Z direction), a metal layer 66, a support base material 67, a resin base material 68, a thin-film transistor (TFT) 69, and an organic EL layer 71. A touch sensor 73 is disposed on the display device 61. Also, a polarization plate 72 is disposed over the touch sensor 73, with a fifth adhesive layer 970 interposed therebetween. Also, the wiring board 10 is disposed over the polarization plate 72, with the third adhesive layer 950 interposed therebetween. A decorative film 74 and the cover glass (surface protection plate) 75 are disposed over the wiring board 10, with a fourth adhesive layer 960 interposed therebetween.

The metal layer 66 is situated on the opposite side from the light-emitting face 64 (minus side in Z direction) than an organic luminescent layer (luminant) 86 of the organic EL layer 71. This metal layer 66 serves a role to protect the display device 61 from electromagnetic waves emitted by other electronic equipment that is not illustrated, situated on the outside of the display device 61. The metal layer 66 may be made of a metal with good conductivity, such as copper or the like, for example. The thickness of the metal layer 66 may be 1 μm or more and 100 μm or less, for example, and preferably is 10 μm or more and 50 μm or less.

The support base material 67 is disposed on the metal layer 66. The support base material 67 supports the entire display device 61, and may be made of a film that has flexibility, for example. Polyethylene terephthalate, for example, can be used as the material of the support base material 67. The thickness of the support base material 67 may be 75 μm or more and 300 μm or less, and preferably is 100 μm or more and 200 μm or less, for example.

The resin base material 68 is disposed on the support base material 67. The resin base material 68 is for supporting the thin-film transistor 69, the organic EL layer 71, and so forth, and is made of a flat layer that has flexibility. The resin base material 68 may be formed by coating using a technique such as die coating, ink-jet coating, spray coating, plasma CVD or thermal CVD, capillary coating, slit-and-spin coating, central dripping, or the like. Colored polyimide, for example, can be used for the resin base material 68. The thickness of the resin base material 68 may be 7 μm or more and 30 μm or less, and preferably is 10 μm or more and 20 μm or less, for example.

The thin-film transistor (TFT) 69 is disposed on the resin base material 68. The thin-film transistor 69 is for driving the organic EL layer 71, and is arranged to control voltage applied to a first electrode 850 and a second electrode 870, which will be described later, of the organic EL layer 71. The thin-film transistor 69 may have an insulating layer, a gate electrode, a source electrode, and a drain electrode, which are not illustrated.

The thin-film transistor 69 has an insulating layer 81, and a gate electrode 82, a source electrode 83, and a drain electrode 84, which are embedded in the insulating layer 81. The insulating layer 81 is configured by laminating a material that has electrical insulating properties, for example, and any of known organic materials and inorganic materials can be used. Examples of materials that may be used for the insulating layer 81 include silicon oxide (SiO₂), silicon nitride (SiNx), silicon oxynitride (SiON), silicon nitride (SiN), and aluminum oxide (AlOx). A molybdenum-tungsten alloy, a laminate of titanium and aluminum, and so forth, for example, can be employed for the gate electrode 82. As for the source electrode 83 and the drain electrode 84, a laminate of titanium and aluminum, a laminate of copper manganese, copper, and molybdenum, and so forth, can be used, for example.

The organic EL layer 71 is disposed on the thin-film transistor 69 and is electrically connected to the thin-film transistor 69. The organic EL layer 71 has the first electrode (reflector electrode, anode electrode) 850 that is disposed above the resin base material 68, the organic luminescent layer (luminant) 86 disposed on the first electrode 850, and the second electrode (transparent electrode, cathode electrode) 870 disposed on the organic luminescent layer 86. Also, a bank 88 is formed on the thin-film transistor 69 to cover end edges of the first electrode 850. Being surrounded by this bank 88 forms openings corresponding to each pixel, and the organic luminescent layer 86 described above is disposed in this opening. Further, the first electrode 850, the organic luminescent layer 86, the second electrode 870, and the bank 88 are sealed by a sealing resin 89. Note that here, the first electrode 850 makes up the anode electrode, and the second electrode 870 makes up the cathode electrode. However, the polarities of the first electrode 850 and the second electrode 870 are not limited in particular.

The first electrode 850 is formed above the resin base material 68 by a technique such as sputtering, vapor deposition, ion plating, CVD, and so forth. The material used for the first electrode 850 is preferably a material that enables efficient hole injection, and examples thereof include metal materials such as aluminum, chromium, molybdenum, tungsten, copper, silver, gold, alloys thereof, and so forth.

The organic luminescent layer (luminant) 86 has a function of an excitation state being generated by injection and recoupling of holes and electrons, thereby emitting light. The organic luminescent layer 86 is formed on the first electrode 850 by vapor deposition, nozzle coating in which a coating liquid is coated from a nozzle, or printing such as ink jet or the like. A material that contains a fluorescent organic material configured to emit light under application of a predetermined voltage is preferable for the organic luminescent layer 86, examples of which include quinolinol complexes, oxazole complexes, various types of laser dyes, polyparaphenylene vinylene, and so forth. Note that a plurality of the organic luminescent layers 86 is one of a red luminescent layer, a green luminescent layer, and a blue luminescent layer, with red luminescent layers, green luminescent layers, and blue luminescent layers being formed repetitively arrayed.

The second electrode 870 is formed on the organic luminescent layer 86. The second electrode 870 may be formed by techniques such as, for example, sputtering, vapor deposition, ion plating, CVD, or the like. A material that lends itself to electron injection and has good light-transmitting properties is preferably used for the second electrode 870. Specific examples include indium tin oxide (ITO) indium zinc oxide (IZO), lithium oxide, cesium carbonate, and so forth.

The bank 88 is formed by using an organic material that has insulating properties, such as resin or the like. Examples of organic materials used for forming the bank 88 include acrylic-based resins, polyimide-based resins, novolac-type phenolic resin, and so forth.

The sealing resin 89 is disposed on the bank 88 and on the second electrode 870. The sealing resin 89 is for protecting the organic luminescent layer 86. Silicon resin or acrylic-based resin, for example, can be used for the sealing resin 89. The thickness of the sealing resin 89 may be 7 μm or more and 30 μm or less, for example, and preferably is 10 μm or more and 20 μm or less.

Note that light emitted at the organic EL layer 71 is extracted from above the sealing resin 89. Thus, the display device 61 according to the present embodiment is a so-called top-emission type display device.

The touch sensor 73 is disposed over the organic EL layer 71. This touch sensor 73 detects and outputs touch position data when a finger or the like is brought into contact with the display device 61 from above the image display device 60. The thickness of the touch sensor 73 may be 0.1 μm or more and 3.0 μm or less, and preferably is 0.2 μm or more and 1.5 μm or less, for example.

The touch sensor 73 may include the conductive layer 76. The conductive layer 76 is grounded, and is electrically connected to a GND electrode that is ground potential. The conductive layer 76 may regulate a reference potential for measuring capacitance therebetween with a sensing electrode of the touch sensor 73. In this case, the conductive layer 76 may be provided with a sensing electrode layer on the display device 61 side, with an insulating layer interposed therebetween. The conductive layer 76 may be formed by a technique such as sputtering, vapor deposition, ion plating, CVD, or the like, for example. A material that lends itself to electron injection and has good light-transmitting properties is preferably used as the material for the conductive layer 76. Specific examples include indium tin oxide (ITO) indium zinc oxide (IZO), lithium oxide, cesium carbonate, and so forth. The conductive layer 76 may be a metal mesh. Transmittance of visible light rays of the conductive layer 76 may be 85% or more, and preferably is 90% or more. Note that there is no limit in particular to the transmittance of visible light rays of the conductive layer 76, but this may be, for example, 100% or less.

The conductive layer 76 is situated on the display device 61 side in the thickness direction, as viewed from the mesh wiring layer 20. The conductive layer 76 is a layer of a conductor that is the closest to the mesh wiring layer 20 in the thickness direction. There is no substantive layer of conductor between the mesh wiring layer 20 and the conductive layer 76. The layers between the mesh wiring layer 20 and the conductive layer 76 make up a dielectric layer. The dielectric layer according to the present embodiment does not necessarily have to be the conductive layer 76 of the touch sensor 73. In a case in which a layer of a conductor is present closer to the mesh wiring layer 20 than the conductive layer 76, this layer of conductor makes up the conductive layer.

The fifth adhesive layer 970 is an adhesive layer that bonds the polarization plate 72 to the touch sensor 73. The fifth adhesive layer 970 may be an OCA (Optical Clear Adhesive) layer. The fifth adhesive layer 970 made of the OCA layer has optical transparency. The thickness of the fifth adhesive layer 970 may be, for example, 10 μm or more and 50 μm or less, and preferably is 15 μm or more and 30 μm or less. The fifth adhesive layer 970 may be made of a similar material as that of a later-described fourth adhesive layer 960 and/or third adhesive layer 950.

The polarization plate 72 is disposed over the touch sensor 73 with the fifth adhesive layer 970 interposed therebetween. The polarization plate 72 is for filtering light from the organic EL layer 71. This polarization plate 72 may be a circular polarization plate. The polarization plate 72 may have a polarizer, and a pair of protective films having translucency, applied to both faces of the polarizer. The thickness of the polarization plate 72 may be, for example, 15 μm or more and 200 μm or less, and preferably is 50 μm or more and 150 μm or less.

The third adhesive layer 950 is an adhesive layer that directly or indirectly bonds the display device 61 to the wiring board 10. The third adhesive layer 950 has optical transparency. The third adhesive layer 950 has a greater area than the substrate 11 of the wiring board 10. Transmittance of visible light rays of the third adhesive layer 950 may be 85% or more, and preferably is 90% or more. Note that there is no upper limit in particular to the transmittance of visible light rays of the third adhesive layer 950, but this may be, for example, 100% or less. Note that the term visible light rays refers to light rays having a wavelength of 400 nm or higher and 700 nm or lower. Also, the term transmittance of visible light rays of 85% or more means that transmittance of the entire wavelength domain of 400 nm or higher and 700 nm or lower is 85% or more when light absorbance is measured for the third adhesive layer 950 using a known spectrophotometer (e.g., spectroscope: V-670 manufactured by JASCO Corporation).

The third adhesive layer 950 may be an OCA (Optical Clear Adhesive) layer. The OCA layer is a layer that is fabricated as follows, for example. First, a curable adhesive layer composition that is in a liquid state and that includes a polymerizable compound is coated on a releasing film of polyethylene terephthalate (PET) or the like. Next, the curable adhesive layer composition is cured by using ultraviolet rays (UV) for example, thereby obtaining an OCA sheet. This OCA sheet is applied to an object, following which the releasing film is removed by separation, thereby obtaining the OCA layer. The material of the third adhesive layer 950 may be an acrylic-based resin, a polyester-based resin, a silicone-based resin, a urethane-based resin, or the like.

The storage elastic modulus of the third adhesive layer 950 at 25° C. may be 1×10⁴ PA or more, and preferably is 5×10⁴ PA or more. There is no upper limit in particular to the storage elastic modulus of the third adhesive layer 950 at 25° C., but this may be, for example, 1×10¹⁰ PA or less. Setting the storage elastic modulus of the third adhesive layer 950 to be high in this way makes the third adhesive layer 950 firm. In this case, the levelness of the wiring board 10 and the conductive layer 76 can be raised. Accordingly, in a case of using the wiring board 10 as an antenna, deterioration in antenna characteristics can be suppressed. In a case in which the third adhesive layer 950 is an OCA layer, for example, examples of a material of which the storage elastic modulus at 25° C. is 1×10⁴ PA or more include acrylic-based resin, silicone-based resin, and so forth. The storage elastic modulus of the third adhesive layer 950 can be measured using Pheogel-E4000 manufactured by UBM, or an equivalent device. Samples used are of a size of 1.0±0.1 mm thick, 5.0±0.5 mm wide, and 30 mm or more long.

Measurement conditions of the storage elastic modulus are measurement mode: temperature-dependent, measurement temperature range is 0 or higher and 101° C. or lower, step temperature is 4° C., temperature rise rate is 4° C./minute, frequency: 10 Hz, strain waveform is sine wave, measurement jig is tensile, measurement is performed at strain control 3 μm, and value is read at 25±1° C.

In-plane average thickness T₁₂ of the third adhesive layer 950 may be, for example, 15 μm or more and 500 μm or less, and preferably is 20 μm or more and 250 μm or less. The in-plane average thickness T₁₂ of the third adhesive layer 950 is the average thickness in the plane of the third adhesive layer 950, and refers to the distance in the direction normal to the surface of the third adhesive layer 950. Also, T₂ₘᵢₙ≥0.9 T₂ₘₐₓ may hold where the in-plane greatest thickness of the third adhesive layer 950 is T₂ₘₐₓ and the in-plane smallest thickness of the third adhesive layer 950 is T₂ₘᵢₙ (≤T₂ₘₐₓ). Also, T₂ₘᵢₙ≥0.95 T₂ₘₐₓ is preferable, and T₂ₘᵢₙ≥0.99 T₂ₘₐₓ is even more preferable. Thus, making the thickness of the third adhesive layer 950 to be uniform in the plane thereof can increase the levelness with respect to the wiring board 10 and the conductive layer 76. Accordingly, in a case of using the wiring board 10 as an antenna, the antenna characteristics can be sufficiently improved. The in-plane greatest thickness T₂ₘₐₓ of the third adhesive layer 950 and the in-plane smallest thickness T₂ₘᵢₙ thereof respectively refer to the greatest value and smallest value of thickness in the plane of the third adhesive layer 950, and refer to the distance in the direction normal to the surface of the third adhesive layer 950. The in-plane greatest thickness T₂ₘₐₓ of the third adhesive layer 950 and the in-plane smallest thickness T₂ₘᵢₙ thereof are found from SEM photography, following forming cross-sections of the third adhesive layer 950 for each using a microtome.

The wiring board 10 is disposed on the light-emitting face 64 side with respect to the display device 61, as described earlier. In this case, the wiring board 10 is situated between the third adhesive layer 950 and the fourth adhesive layer 960. More specifically, a partial region of the substrate 11 of the wiring board 10 is disposed in a partial region between the third adhesive layer 950 and the fourth adhesive layer 960. In regions where the wiring board 10 is not present, the third adhesive layer 950 and the fourth adhesive layer 960 are directly bonded together. In this case, the third adhesive layer 950, the fourth adhesive layer 960, the display device 61, the decorative film 74, and the cover glass 75 each have an area that is greater than the substrate 11 of the wiring board 10. Thus, disposing the substrate 11 of the wiring board 10 in a partial region and not the entire face of the image display device 60 in plan view enables the overall thickness of the image display device 60 to be made thinner.

The wiring board 10 has the substrate 11 that has transparency, and the mesh wiring layer 20 that is disposed on the substrate 11. The power supply unit 40 is electrically connected to the mesh wiring layer 20. The power supply unit 40 is electrically connected to the communication module 63. Also, part of the wiring board 10 is not disposed between the third adhesive layer 950 and the fourth adhesive layer 960, and protrudes outward (minus side in Y direction) from between the third adhesive layer 950 and the fourth adhesive layer 960. Specifically, the region of the wiring board 10 on which the power supply unit 40 is provided protrudes outward. Thus, electrical connection of the power supply unit 40 and the communication module 63 can be easily performed. On the other hand, the region of the wiring board 10 on which the mesh wiring layer 20 is provided is situated between the third adhesive layer 950 and the fourth adhesive layer 960. Note that details of the wiring board 10 will be described later.

The fourth adhesive layer 960 is an adhesive layer that directly or indirectly bonds the wiring board 10 to the cover glass 75. The fourth adhesive layer 960 has a greater area than the substrate 11 of the wiring board 10. The fourth adhesive layer 960 has optical transparency, in the same way as the third adhesive layer 950. Transmittance of visible light rays of the fourth adhesive layer 960 may be 85% or more, and preferably is 90% or more. Note that there is no upper limit in particular to the transmittance of visible light rays of the fourth adhesive layer 960, but this may be, for example, 100% or less. The fourth adhesive layer 960 may be an OCA (Optical Clear Adhesive) layer. The material of the fourth adhesive layer 960 may be an acrylic-based resin, a polyester-based resin, a silicone-based resin, a urethane-based resin, or the like. Thickness T₁₃ of the fourth adhesive layer 960 may be, for example, 15 μm or more and 500 μm or less, and preferably is 20 μm or more and 250 μm or less. The fourth adhesive layer 960 may be made from the same material as the third adhesive layer 950.

The storage elastic modulus of the fourth adhesive layer 960 at 25° C. may be 1×10⁴ PA or more, and preferably is 5×10⁴ PA or more. There is no upper limit in particular to the storage elastic modulus of the fourth adhesive layer 960 at 25° C., but this may be, for example, 1×10¹⁰ PA or less. The storage elastic modulus of the fourth adhesive layer 960 can be measured in the same way as the storage elastic modulus of the third adhesive layer 950.

In the present embodiment, a distance Lz between the mesh wiring layer 20 and the conductive layer 76 in the direction normal to the conductive layer 76 is substantially uniform in the plane. Accordingly, the levelness of the mesh wiring layer 20 with respect to the conductive layer 76 is uniform in the plane. Specifically, a relation of L_{zmin}≥0.9 L_{zmax} holds where the shortest distance between the mesh wiring layer 20 and the conductive layer 76 in the direction normal to the conductive layer 76 is L_{zmin}, and the longest distance between the mesh wiring layer 20 and the conductive layer 76 is L_{zmax} (≥ L_{zmin}). Also, L_{zmin}≥0.95 L_{zmax} is preferable, L_{zmin}≥0.97 L_{zmax} is more preferable, and L_{zmin}≥0.99 L_{zmax} is even more preferable. Making the distance Lz between the mesh wiring layer 20 and the conductive layer 76 to be substantially uniform in the plane in this way can increase the levelness of the wiring board 10 and the conductive layer 76. Accordingly, in a case of using the wiring board 10 as an antenna, the antenna characteristics can be improved. In this case, stable transmission/reception of radio waves according to design can be carried out using the wiring board 10.

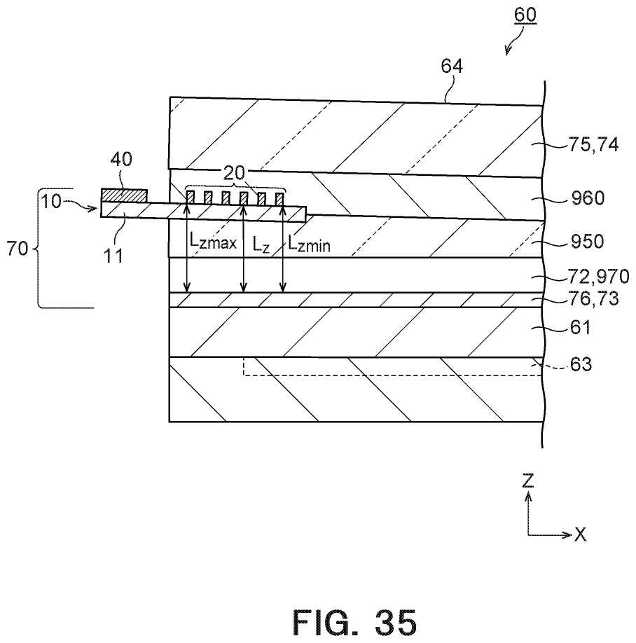

The longest distance L_{zmax} and the shortest distance L_{zmin} between the mesh wiring layer 20 and the conductive layer 76 respectively refer to the greatest value and the smallest value of the distance Lz between the mesh wiring layer 20 and the conductive layer 76 as measured in the direction normal to the conductive layer 76 (see FIG. 35). Note that places where the distance between the mesh wiring layer 20 and the conductive layer 76 is greatest and smallest generally are located on a periphery of the mesh wiring layer 20. Also, in a case in which there is a region in which the mesh wiring layer 20 and the conductive layer 76 do not overlap as viewed in the direction normal to the conductive layer 76, the longest distance L_{zmax} and the shortest distance L_{zmin} are defined in a region in which the mesh wiring layer 20 and the conductive layer 76 overlap. The longest distance L_{zmax} and the shortest distance L_{zmin} are each measured as follows. First, a sample including a cross-section of the image display device laminate 70 is created by a microtome, so as to include the outermost periphery of the mesh wiring layer 20. Next, the distance Lz between the mesh wiring layer 20 and the conductive layer 76 is found from SEM photography, using this sample. The largest value of the distance Lz is taken as the longest distance L_{zmax}, and the smallest value of the distance Lz is taken as the shortest distance L_{zmin}.

As described above, the image display device laminate 70 is made up of at least the wiring board 10, the third adhesive layer 950, and the conductive layer 76. In the present embodiment, such an image display device laminate 70 is provided as well.

The decorative film 74 is disposed on the fourth adhesive layer 960. This decorative film 74 opens at a portion over the display region of the display device 61 as viewed from the observer side, for example, and shields light at portions other than the display region. That is to say, the decorative film 74 is disposed so as to cover edge portions of the display device 61 as viewed from the observer side.

### [Configuration of Wiring Board]

Next, the configuration of the wiring board will be described with reference to FIG. 33 and FIG. 34.

As illustrated in FIG. 33 and FIG. 34, regarding the wiring board 10 of the present embodiment, the wiring board 10 is on the light-emitting face 64 side from the display device 61, and is disposed between the third adhesive layer 950 and the fourth adhesive layer 960.

It is sufficient for the material of the substrate 11 to be a material that has transparency in the visible light domain, and electrical insulating properties. While the material of the substrate 11 is polyethylene terephthalate in the present embodiment, this is not restrictive.

Also, the substrate 11 may be either film-like or plate-like. Accordingly, there is no limit on the thickness of the substrate 11 in particular, and can be selected as appropriate in accordance with the usage. As one example, the in-plane average thickness T₁ of the substrate 11 (see FIG. 2 and FIG. 5) may be in a range of, for example, 10 μm or more and 200 μm or less. Also, the in-plane average thickness T₁ of the substrate 11 preferably is 10 μm or more and 50 μm or less, and more preferably is 15 μm or more and 25 μm or less, for example. Making the in-plane average thickness T₁ of the substrate 11 to be 10 μm or more enables the strength of the wiring board 10 to be maintained, and to make the later-described first-direction wiring lines 21 and second-direction wiring lines 22 of the mesh wiring layer 20 less likely to deform. Also, making the average thickness T₁ of the substrate 11 to be 200 μm or more enables stepped portions to be suppressed from being formed in the third adhesive layer 950 and the fourth adhesive layer 960 at the peripheral edge of the substrate 11, and the presence of the substrate 11 can be made to be less visually recognizable by the observer.

Also, T₁ₘᵢₙ≥0.9 T₁ₘₐₓ may hold where the in-plane greatest thickness of the substrate 11 is T₁ₘₐₓ and the in-plane smallest thickness of the substrate 11 is T₁ₘᵢₙ (≤T₁ₘₐₓ). Further, T₁ₘᵢₙ≥0.95 T₁ₘₐₓ IS preferable, and T₁ₘᵢₙ≥0.99 T₁ₘₐₓ is even more preferable. Making the thickness of the substrate 11 to be uniform in the plane in this way can increase the levelness of the wiring board 10 and the conductive layer 76. Accordingly, in a case of using the wiring board 10 as an antenna, the antenna characteristics can be sufficiently improved. The in-plane greatest thickness T₁ₘₐₓ and the in-plane smallest thickness T₁ₘᵢₙ of the substrate 11 respectively refer to the greatest value and smallest value of thickness in the plane of the substrate 11. The in-plane greatest thickness T₁ₘₐₓ and the in-plane smallest thickness T₁ₘᵢₙ of the substrate 11 are each found from SEM photography, following forming cross-sections of the third adhesive layer 950 using a microtome.

### [Manufacturing Method of Wiring Board]

The wiring board according to the present embodiment can be fabricated by the method illustrated in FIGS. 7(a) to 7(f), for example.

### Effects of Present Embodiment

Next, the effects of the present embodiment having such a configuration will be described.

As illustrated in FIG. 33 to FIG. 35, the wiring board 10 is assembled into the image display device 60 that has the display device 61. The wiring board 10 is disposed over the display device 61, with the touch sensor 73, the fifth adhesive layer 970, the polarization plate 72, and the third adhesive layer 950 interposed therebetween. In doing so, the wiring board 10 is disposed such that the mesh wiring layer 20 and the conductive layer 76 are maintained in a level state. Specifically, the wiring board 10 is disposed such that the relation of L_{zmin}≥0.9 L_{zmax} holds with regard to the shortest distance L_{zmin} and the longest distance L_{zmax} between the mesh wiring layer 20 and the conductive layer 76. Also, the mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

Now, at the time of performing transmission/reception of radio waves using the mesh wiring layer 20 of the wiring board 10, there is concern that antenna characteristics of the mesh wiring layer 20 will deteriorate unless the mesh wiring layer 20 and the conductive layer 76 are disposed level to each other.

According to the present embodiment, as described above, L_{zmin}≥0.9 L_{zmax} holds where the shortest distance between the mesh wiring layer 20 and the conductive layer 76 in the direction normal to the conductive layer 76 is L_{zmin}, and the longest distance between the mesh wiring layer 20 and the conductive layer 76 in the direction normal to the conductive layer 76 is L_{zmax}. In this case, the mesh wiring layer 20, and the conductive layer 76 that is the metal layer closest to the mesh wiring layer 20, are disposed in parallel to each other. Accordingly, the conductive layer 76 and the mesh wiring layer 20 are not strongly electrically coupled, and external emission of radio waves from the housing 62 can be suppressed from becoming weak. As a result, in a case of using the wiring board 10 as an antenna, the antenna characteristics of the mesh wiring layer 20 can be suppressed from deteriorating.

In the present embodiment, the storage elastic modulus of the third adhesive layer 950 at 25° C. may be 1×10⁴ PA or more. Thus, the third adhesive layer 950 is firm, and accordingly the levelness of the wiring board 10 and the conductive layer 76 can be raised. Accordingly, in a case of using the wiring board 10 as an antenna, deterioration in antenna characteristics can be suppressed.

Also, in the present embodiment, T₁ₘᵢₙ≥0.9 T₁ₘₐₓ may hold where the in-plane greatest thickness of the substrate 11 is T₁ₘₐₓ and the in-plane smallest thickness of the substrate 11 is T₁ₘᵢₙ. Thus, making the thickness of the substrate 11 to be uniform can increase the levelness with respect to the wiring board 10 and the conductive layer 76. Accordingly, in a case of using the wiring board 10 as an antenna, deterioration in antenna characteristics can be suppressed.

Also, in the present embodiment, T₂ₘᵢₙ≥0.9 T₂ₘₐₓ may hold where the in-plane greatest thickness of the third adhesive layer 950 is T₂ₘₐₓ and the in-plane smallest thickness of the third adhesive layer 950 is T₂ₘᵢₙ. Thus, making the thickness of the third adhesive layer 950 to be uniform can increase the levelness with respect to the wiring board 10 and the conductive layer 76. Accordingly, in a case of using the wiring board 10 as an antenna, deterioration in antenna characteristics can be suppressed.

Also, in the present embodiment, the polarization plate 72 may be positioned between the wiring board 10 and the touch sensor 73. Accordingly, a gap can be formed between the substrate 11 and the touch sensor 73 using the polarization plate 72 that substantially does not contain metal. Accordingly, the overall thickness of the image display device 60 can be suppressed from increasing as compared to a case of the polarization plate 72 being situated between the touch sensor 73 and the display device 61, and also deterioration in antenna performance of the mesh wiring layer 20 can be suppressed.

The plurality of components disclosed in the above embodiments and modifications can be appropriately combined as necessary. Alternatively, some of the components may be omitted from all components shown in the above embodiments and modifications.

1. An image display device laminate, comprising:
a wiring board that has a substrate including a first face and a second face situated on an opposite side from the first face, and a mesh wiring layer disposed on the first face of the substrate;
a first adhesive layer situated on a first face side of the substrate;
a second adhesive layer situated on a second face side of the substrate; and
an intermediate layer situated in at least one of a position between the wiring board and the first adhesive layer and a position between the wiring board and the second adhesive layer, wherein
the substrate has transparency, and
a partial region of the substrate is disposed in a partial region between the first adhesive layer and the second adhesive layer.

2. The image display device laminate according to claim 1, wherein the intermediate layer is situated between the wiring board and the first adhesive layer, and is also situated between the wiring board and the second adhesive layer.

3. The image display device laminate according to claim 1, wherein a thickness of the intermediate layer is 1 μm or more and 50 μm or less.

4. The image display device laminate according to claim 1, wherein a refractive index of the intermediate layer is 1.4 or more and 1.6 or less.

5. The image display device laminate according to claim 1, wherein a difference between a refractive index of the intermediate layer and a refractive index of the first adhesive layer is 0.1 or less, a difference between the refractive index of the intermediate layer and a refractive index of the substrate is 0.1 or less, and a difference between the refractive index of the intermediate layer and a refractive index of the second adhesive layer is 0.1 or less.

6. The image display device laminate according to claim 1, wherein a dielectric dissipation factor of the substrate is 0.002 or less.

7. The image display device laminate according to claim 1, wherein a relative permittivity of the substrate is 2 or more and 10 or less.

8. The image display device laminate according to claim 1, wherein the wiring board has a radio wave transmission/reception function.

9. The image display device laminate according to claim 1, wherein the wiring board further has a power supply unit that is electrically connected to the mesh wiring layer, and the mesh wiring layer includes a transfer portion that is connected to the power supply unit and a transmission/reception unit that is connected to the transfer portion.

10. An image display device, comprising:
the image display device laminate according to claim 1; and
a display device that is laminated on the image display device laminate.

11. An image display device laminate, comprising:
a wiring board that has a substrate including a first face, a second face situated on an opposite side from the first face, and a third face situated between the first face and the second face, and a mesh wiring layer disposed on the first face of the substrate;
a first adhesive layer situated on a first face side of the substrate; and
a second adhesive layer situated on a second face side of the substrate, wherein
the substrate has transparency,
a partial region of the substrate is disposed in a partial region between the first adhesive layer and the second adhesive layer,
the third face of the substrate is covered by at least one of the first adhesive layer and the second adhesive layer, and
a surface roughness Ra of the third face is 0.005 μm or more and 0.5 μm or less.

12. The image display device laminate according to claim 11, wherein
a thickness of the substrate is 2 μm or more and 50 μm or less.

13. The image display device laminate according to claim 11, wherein
a thickness of the first adhesive layer is 1.5 times or more a thickness of the substrate, and is 300 μm or less.

14. The image display device laminate according to claim 11, wherein
a thickness of the second adhesive layer is 1.5 times or more a thickness of the substrate, and is 300 μm or less.

15. The image display device laminate according to claim 11, wherein the first adhesive layer and the second adhesive layer each contain an acrylic-based resin.

16. The image display device laminate according to claim 11, wherein a dummy wiring layer that is electrically isolated from the mesh wiring layer is provided on a periphery of the mesh wiring layer.

17. The image display device laminate according to claim 11, wherein a dielectric dissipation factor of the substrate is 0.002 or less.

18. The image display device laminate according to claim 11, wherein a relative permittivity of the substrate is 2 or more and 10 or less.

19. The image display device laminate according to claim 11, wherein the wiring board has a radio wave transmission/reception function.

20. The image display device laminate according to claim 11, wherein the wiring board further has a power supply unit that is electrically connected to the mesh wiring layer, and the mesh wiring layer includes a transfer portion that is connected to the power supply unit, and a transmission/reception unit that is connected to the transfer portion.

21. An image display device, comprising:
the image display device laminate according to claim 11; and
a display device that is laminated on the image display device laminate.

22. A module, comprising:
a wiring board that has a substrate including a first face, a second face situated on an opposite side from the first face, and a third face situated between the first face and the second face, a mesh wiring layer disposed on the first face of the substrate, and a power supply unit that is electrically connected to the mesh wiring layer; and
a power supply line that is electrically connected to the power supply unit, wherein
a surface roughness Ra of the third face is 0.005 μm or more and 0.5 μm or less.

23-45. (canceled)
